(19) United States
(12) Patent Application Publication
(10) Pub. No.: US 2026/0148685 A1
(43) Pub. Date: May 28, 2026

(54) DISPLAY DEVICE

(71) Applicant: LG Display Co., Ltd., Seoul (KR)

(72) Inventors: YoungJin Kim, Gyeonggi-do (KR); Jongseong Han, Gyeonggi-do (KR); Jeongwook Lee, Gyeonggi-do (KR); Hyewon Bae, Gyeonggi-do (KR)

(21) Appl. No.: 19/345,357

(22) Filed: Sep. 30, 2025

(30) Foreign Application Priority Data
Nov. 28, 2024 (KR) 10-2024-0173831

(51) Int. Cl. G09G 3/32

(52) U.S. Cl. CPC G09G 3/32; G09G 2300/0861; G09G 2310/0232; G09G 2310/0281; G09G 2310/08; G09G 2320/0233; G09G 2330/021

(57) ABSTRACT

A display device is provided, a first driver disposed in the plurality of peripheral portions and driving the plurality of light emitting devices in the plurality of peripheral portions, a second driver disposed in the central area and driving the plurality of light emitting devices in the central area, wherein the number of light emitting devices driven by the first driver is different from the number of light emitting devices driven by the second driver.

### CROSS-REFERENCE TO RELATED APPLICATIONS

Pursuant to 35 U.S.C. § 119(a), this application claims the benefit and right of priority to Korean Patent Application No. 10-2024-0173831, filed on Nov. 28, 2024, the contents of which are hereby incorporated by reference in its entirety.

### TECHNICAL FIELD

The present disclosure generally relates to a display device.

### BACKGROUND

The display device is applied to various electronic devices such as TVs, mobile phones, laptops, and tablets. The display devices include an organic light emitting display (OLED) that emit light by themselves and a liquid crystal display (LCD) that require a separate light source.

Recently, a display device including a light emitting diode (LED) has attracted attention as a next-generation display device. The light emitting diode is made of an inorganic material, not an organic material. Accordingly, compared to the liquid crystal display or the organic light emitting display device, the display device including the light emitting diode has a faster lighting speed, excellent luminous efficiency, and displays an image having high luminance.

### SUMMARY

In accordance with an aspect of the present disclosure, a display device is provided, comprising a substrate divided into a unit driving area including a plurality of light emitting devices and including a plurality of peripheral portions and a central area different from the plurality of peripheral portions, a first driver disposed in the plurality of peripheral portions and driving the plurality of light emitting devices in the plurality of peripheral portions, a second driver disposed in the central area and driving the plurality of light emitting devices in the central area, and a controller circuit driving the first driver and the second driver, and wherein the number of light emitting devices driven by the first driver is different from the number of light emitting devices driven by the second driver.

It is to be understood that both the foregoing general description and the following detailed description are exemplary and explanatory and are intended to provide further explanation of the inventive concepts as claimed

### BRIEF DESCRIPTION OF THE DRAWINGS

The accompanying drawings, which are included to provide a further understanding of the disclosure and are incorporated in and constitute a part of this application, illustrate implementations of the disclosure and together with the description serve to explain the principle of the disclosure. In the drawings:

FIG. 1 is a diagram illustrating a display device according to implementations of the present disclosure.

FIG. 2 is a plan view of a display device according to an implementation of the present disclosure.

FIG. 3 is a plan view of a display panel according to an implementation of the present disclosure.

FIG. 4 is a plan view of a unit driving area of a display panel according to implementations of the present disclosure.

FIG. 5 is a diagram schematically illustrating a structure of a subpixel of a display panel according to implementations of the present disclosure.

FIG. 6 illustrates a driving timing diagram of n row lines and one column line included in a first sub-driving area of a display panel according to implementations of the present disclosure.

FIG. 7 is a plan view of a display panel according to implementations of the present disclosure.

FIG. 8 is a detailed cross-sectional view of a display panel according to implementations of the present disclosure, and is a cross-sectional view taken along line A-B of FIG. 7.

FIG. 9 is a view illustrating a substrate including a plurality of peripheral portions in a display device according to implementations of the present disclosure.

FIG. 10 is a diagram illustrating a connection relationship between a driver and subpixels disposed in a unit driving area in a display device according to implementations of the present disclosure.

FIG. 11 is a diagram for describing a driving timing of a driver disposed at a peripheral portion of a display device according to implementations of the present disclosure.

FIG. 12 is a diagram illustrating an operation of a controller circuit in a display device according to implementations of the present disclosure.

FIG. 13 is a diagram illustrating data input for each area in a display device according to implementations of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience

### DETAILED DESCRIPTION

Implementations of the disclosure relate to display devices, and more particularly, to a driving architecture and method for display devices that include non-rectangular display areas near the periphery, such as rounded corners. As the display area of a display device deviates from a standard rectangular shape, the number and arrangement of light-emitting devices can become non-uniform. This can lead to challenges in the peripheral portions of the display, where a driving circuit may be connected to column lines that do not have a full set of corresponding light-emitting devices, which can cause voltage-floating artifacts and unintended light emission.

Accordingly, implementations disclosed herein may provide a display device with an improved driving architecture that addresses these challenges. In some implementations, the display substrate is conceptually divided into a central area and a plurality of peripheral portions, with a first driver for the peripheral portions and a second driver for the central area. A controller circuit is connected to provide modified image data to the first driver, wherein the modified data includes black image data for driving instances that correspond to the locations of missing light-emitting devices in the peripheral portions. This application of black image data prevents the corresponding column lines from floating to an undesired voltage. This targeted driving method allows for the seamless presentation of images on a non-rectangular display without artifacts at the peripheral portions (e.g., corners). Furthermore, by preventing unintended light emission, image quality and contrast may be improved, which can contribute to a better overall user experience and potentially lower power consumption.

Advantages and features of the present specification and methods of achieving them will become apparent with reference to preferable implementations, which are described in detail, in conjunction with the accompanying drawings. However, the present specification is not limited to the implementations to be described below and may be implemented in different forms, the implementations are only provided to completely disclose the present disclosure and completely convey the scope of the present disclosure to those skilled in the art, and the present specification is defined by the disclosed claims.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

In addition, the present disclosure has been made in view of the above problems and it is an aspect of the present disclosure to provide a display device capable of reducing size of peripheral part as a driver is not disposed at the periphery (e.g., a corner).

In addition, the present disclosure has been made in view of the above problems and it is an aspect of the present disclosure to provide a display device capable of reducing size of peripheral part as a driver is not disposed at the periphery (e.g., a corner).

In addition, the present disclosure has been made in view of the above problems and it is an aspect of the present disclosure to provide a low-power display device as a driver is not disposed at the periphery (e.g., a corner).

Reference will now be made in detail to implementations of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and implementation methods thereof will be clarified through following implementations described with reference to the accompanying drawings. The present disclosure may, however, be embodied in different forms and should not be construed as limited to the implementations set forth herein. Rather, these implementations are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing implementations of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where ‘comprise’, ‘have’ and ‘include’ described in the present disclosure are used, another portion may be added unless ‘only˜’ is used. The terms of a singular form may include plural forms unless referred to the contrary.

In interpreting the components, it is interpreted as including the error range even if there is no separate explicit description of the error range.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used. The terms, such as “below,” “lower,” “above,” “upper” and the like, may be used herein to describe a relationship between element(s) as illustrated in the drawings. It will be understood that the terms are spatially relative and based on the orientation depicted in the drawings.

A description of a time relationship may include a case in which the temporal precedence relationship is described as “after”, “following”, or “before”, etc., and is not continuous unless “right away” or “directly”, is used.

Although the first, second, and the like are used to describe various components, these components are not limited by these terms. These terms are used only to distinguish one component from another. Therefore, a first component mentioned below may be a second component within a technical idea of a present disclosure.

It will be understood that, although the terms “first,” “second,” “A,” “B,” “(a),” and “(b)” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

If a component is stated to be “connected,” “coupled,” “connected,” or “attached” to another component, that component may be connected, coupled, connected, or attached directly to that other component, but it should be understood that other components may be interposed between each component that may be connected, coupled, connected, or attached indirectly, without any specific description.

It should be understood that if a component or layer is stated to be “in contact” or “overlapping” with another component or layer, the component or layer may be in direct contact or overlapping with another component or layer, but other components may be interposed between each component that may be indirectly in contact or overlapping without particular explicit description.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

“First direction,” “second direction,” “third direction,” “X-axis direction,” “Y-axis direction,” and “Z-axis direction” should not be interpreted only as a geometric relationship perpendicular to each other, but may mean that the configuration of the present disclosure has a wider direction within a range in which the configuration of the present disclosure may functionally act.

Features of each of the various implementations of the present specification may be partially or entirely coupled or combined with each other, technically various interworking and driving are possible, and each of the implementations may be independently implemented with respect to each other or may be implemented together in a related relationship.

Hereinafter, one implementation of the present disclosure will be described in detail with reference to the accompanying drawings.

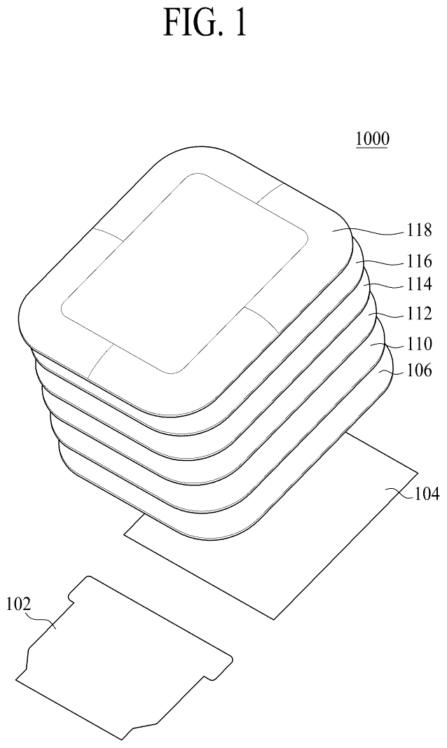

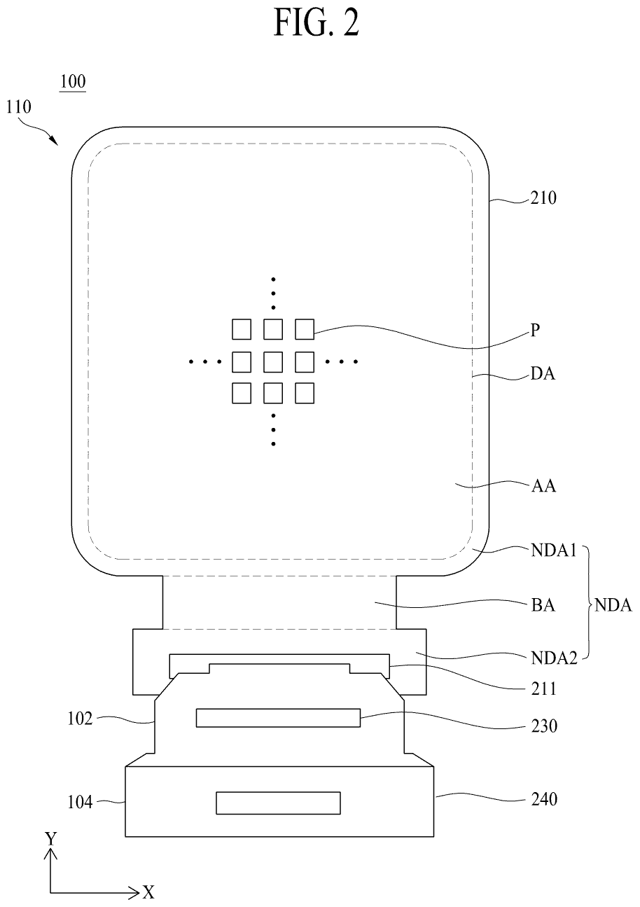

FIG. 1 is a view illustrating a display device according to implementations of the present disclosure, and FIG. 2 is a plan view of the display device according to implementations of the present disclosure.

Referring to FIG. 1, a display device 100 according to implementations of the present disclosure may include a display panel 110, a cover member 118 disposed on the display panel 110, a flexible printed circuit 102 connected to the display panel 110, and a printed circuit board 104 connected to the flexible printed circuit 102.

The display device 100 according to implementations of the present disclosure may further include a support substrate 106 disposed under the display panel 110 to support a lower portion of the display panel 110, a polarizing layer 114 disposed on the display panel 110, a first adhesive layer 112 disposed between the display panel 110 and the polarizing layer 114, and a second adhesive layer 116 disposed between the polarizing layer 114 and the cover member 118.

The display panel 110 may include a substrate 210. The substrate 210 may be a member in which various components such as a plurality of metal layers and a plurality of insulating material layers are formed. The substrate 210 may be made of an insulating material. For example, the substrate 210 may be made of glass or resin. In addition, the substrate 210 may be made of a material having flexibility. For example, the substrate 210 may be made of a plastic material having flexibility, such as polyimide (PI). However, implementations of the present disclosure are not limited thereto.

The display panel 110 may implement information, an image, and/or a picture provided to a user. For example, the display panel 110 may include a display area DA and a non-display area NDA. For example, the substrate 210 may include the display area DA and the non-display area NDA. The display area DA and the non-display area NDA are not limited to the substrate 210, but may be described throughout the display device 100.

The display area DA may be an area in which an image is displayed. The display area DA may include a plurality of pixels P. Each of the plurality of pixels P may include a plurality of subpixels. At least one light emitting device may be disposed in each of the plurality of subpixels. The light emitting device may be configured to be different according to a type of the display device 100. For example, when the display device 100 is an inorganic light emitting display device, the light emitting device may be an inorganic light emitting device and may be a light-emitting diode (LED), a micro light-emitting diode (Micro-LED), or a mini-light-emitting diode (MLED), but implementations of the present disclosure are not limited thereto.

The non-display area NDA may be an area in which no image is displayed. Various wirings and circuits for driving the plurality of pixels P in the display area DA may be disposed in the non-display area NDA. For example, various driving circuits and various wirings may be disposed in the non-display area NDA, and a pad part 211 to which the integrated circuit and the printed circuit are connected may be disposed in the non-display area NDA, but implementations of the present disclosure are not limited thereto.

For example, a driving circuit may include a data driving circuit and/or a gate driving circuit, but implementations of the present disclosure are not limited thereto. Wirings to which a control signal for controlling the driving circuit is supplied may be disposed on the substrate 210. For example, the control signal may include various timing signals including a clock signal, an input data enable signal, and synchronization signals, but implementations of the present disclosure are not limited thereto. The control signal may be supplied to the substrate 210 from an outside of the substrate 210 through the pad part 211. For example, circuit components such as the flexible printed circuit 102 and the printed circuit board 104 may be connected to the pad part 211.

According to the present disclosure, the non-display area NDA may include a first non-display area NDA1, a bending area BA, and a second non-display area NDA2. For example, the first non-display area NDA1 may be an area surrounding at least a portion of the display area DA. The bending area BA may be an area extending from at least one of a plurality of sides of the first non-display area NDA1 and may be a bendable area. The second non-display area NDA2 is an area extending from the bending area BA and may include the pad part 211. For example, the bending area BA may be in a bent state, and the remaining area of the substrate 210 except for the bending area BA may be in a flat state. In this case, as the bending area BA is bent, the second non-display area NDA2 may be located on a rear surface of the display area DA. However, implementations of the present disclosure are not limited thereto.

The display area DA of the substrate 210 or the display device 100 may be configured in various shapes according to the design of the display device 100. For example, the display area DA may be configured in a rectangular shape having four rounded corners in the periphery, but implementations of the present disclosure are not limited thereto. For another example, the display area DA may be configured in a rectangular shape having four corners or a circular shape, but implementations of the present disclosure are not limited thereto.

According to implementations of the present disclosure, a width of the second non-display area NDA2 in which the pad part 211 is disposed may be wider than a width of the bending area BA. In addition, a width of the display area DA may be wider than the width of the bending area BA. Although the width of the bending area BA is shown to be narrower than a width of other areas of the substrate 210, a shape of the substrate 210 including the bending area BA is exemplary, and implementations of the present disclosure are not limited thereto.

Referring to FIGS. 1 and 2, the flexible printed circuit 102 and the printed circuit board 104 may be disposed under the display panel 110. The flexible printed circuit 102 and the printed circuit board 104 may be disposed at one edge of the display panel 110, but implementations of the present disclosure are not limited thereto. One side of the flexible printed circuit 102 may be connected to the display panel 110, and the other side of the flexible printed circuit 102 may be connected to the printed circuit board 104, but implementations of the present disclosure are not limited thereto. The flexible printed circuit 102 may be a flexible film, but implementations of the present disclosure are not limited thereto.

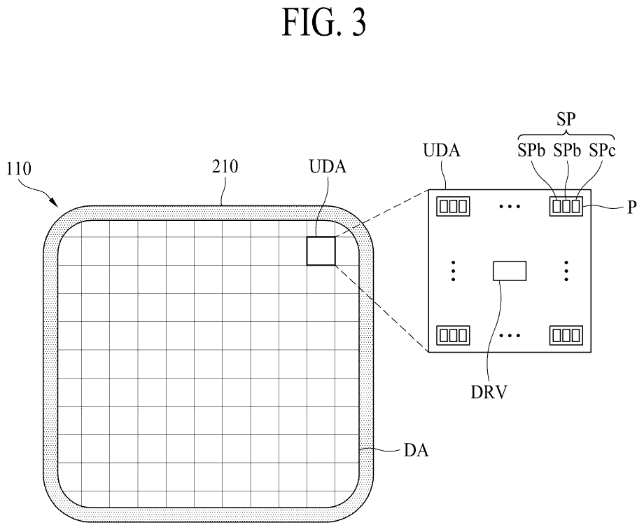

The pad part 211 disposed in the second non-display area NDA2 includes a plurality of pads, and driving components including at least one flexible printed circuit 102 and the printed circuit board 104 may be attached or bonded. The plurality of pads included in the pad part 211 are electrically connected to at least one flexible printed circuit 102, and may transmit various signals (or power) from the printed circuit board 104 and at least one flexible printed circuit 102 to a driving circuit (for example, the driver DRV of FIG. 3) disposed in the display area DA.

The flexible printed circuit 102 may be a film in which various components are disposed on a flexible base film. For example, a first circuit component 230, such as a gate driving integrated circuit and/or a data driving integrated circuit, may be disposed in one or more flexible printed circuits 102, but implementations of the present disclosure are not limited thereto. The first circuit component 230 may be a component that processes data and a driving signal for displaying an image. The first circuit component 230 may be disposed by a method such as a chip on glass (COG) or a chip on film (COF) or a tape carrier package (TCP) according to a method of being mounted, but implementations of the present disclosure are not limited thereto. The flexible printed circuit 102 may be attached to or bonded on the plurality of pads through a conductive adhesive layer, but implementations of the present disclosure are not limited thereto.

The printed circuit board 104 may be a component that is electrically connected to the flexible printed circuit 102 and supplies a signal to the first circuit component 230. The printed circuit board 104 may be disposed at one side of the flexible printed circuit 102 and may be electrically connected to the flexible printed circuit 102. Various components for supplying various signals to the first circuit component 230 may be disposed on the printed circuit board 104. For example, various second circuit components 240 such as a timing controller, a power supply unit, a memory, a processor, etc. may be disposed on the printed circuit board 104. For example, the second circuit component 240 disposed on the printed circuit board 104 may include a timing controller and/or a power management integrated circuit (PMIC), but implementations of the present disclosure are not limited thereto.

The printed circuit board 104 may include at least one hole, but implementations of the present disclosure are not limited thereto. An internal component that senses ambient light or temperature that may be provided to a plurality of sensors may be disposed in an area corresponding to at least one hole. For example, the internal component may include an ambient light sensor (ALS) or a temperature sensor, but implementations of the present disclosure are not limited thereto. For example, the hole may be a transmissive hole or the like, but implementations of the present disclosure are not limited thereto.

Referring to FIG. 1, the polarizing layer 114 may be disposed on the display panel 110, and light generated from an external light source may be prevented or reduced from entering the display panel 110 and affecting the light emitting device.

The cover member 118 may be disposed on the polarizing layer 114 and may be a member for protecting the display panel 110.

The second adhesive layer 116 may be disposed between the polarizing layer 114 and the cover member 118. The second adhesive layer 116 may attach the cover member 118 to the display panel 110 or the polarizing layer 114.

The first adhesive layer 112 may be disposed between the display panel 110 and the polarizing layer 114. The first adhesive layer 112 may attach the polarizing layer 114 to the display panel 110. The first adhesive layer 112 may be omitted.

Each of the first adhesive layer 112 and the second adhesive layer 116 may include an optically clear adhesive (OCA), an optically clear resin (OCR), or a pressure sensitive adhesive (PSA), but implementations of the present disclosure are not limited thereto.

The support substrate 106 may be disposed between the display panel 110 and the printed circuit board 104 to reinforce rigidity of the display panel 110. The support substrate 106 may be a back plate, but implementations of the present disclosure are not limited thereto.

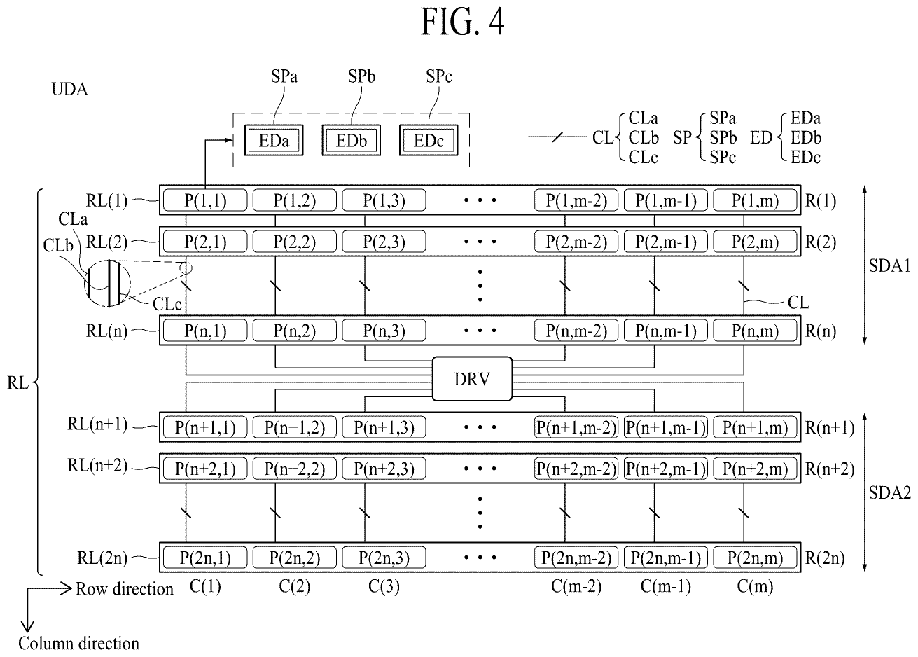

FIG. 3 is a plan view of a display panel according to an implementation of the present disclosure, and FIG. 4 is a plan view of a unit driving region of a display panel according to implementations of the present disclosure.

Referring to FIG. 3, the display area DA of the display panel 110 according to implementations of the present disclosure may include a plurality of unit driving areas UDA.

Referring to FIG. 3, the display panel 110 according to implementations of the present disclosure may include a driver DRV disposed in each of the plurality of unit driving areas UDA. For example, the driver DRV may be a driving chip manufactured using a metal-oxide-silicon field effect transistor (MOSFET) manufacturing process on a semiconductor substrate, but implementations of the present disclosure are not limited thereto.

Referring to FIG. 3, each of the plurality of unit driving areas UDA may be a driving area driven by one driver DRV. That is, the plurality of unit driving areas UDA may be independent driving areas driven by different drivers DRV.

Referring to FIG. 3, the display panel 110 according to implementations of the present disclosure may include a substrate 210 including the display area DA and a plurality of pixels P disposed in a matrix form in the display area DA.

The plurality of pixels P may be disposed in each of the plurality of unit driving areas UDA. Each of the plurality of pixels P may include a plurality of sub-pixels SP. Each of the plurality of sub-pixels SP may include at least one light emitting device.

For example, the plurality of subpixels SP may include a first subpixel SPa, a second subpixel SPb, and a third subpixel SPc, but are not limited thereto. The first subpixel SPa may include a first light emitting device that emits first color light, the second subpixel SPb may include a second light emitting device that emits second color light, and the third subpixel SPc may include a third light emitting device that emits third color light. For example, the first color light, the second color light, and the third color light may be red light, green light, and blue light, but are not limited thereto.

Referring to FIG. 4, the display panel 110 according to implementations of the present disclosure may include a plurality of light emitting devices ED. Each of the plurality of subpixels SP may include the light emitting device ED.

For example, the first sub-pixel SPa may include the first light emitting device EDa, the second sub-pixel SPb may include the second light emitting device EDb, and the third sub-pixel SPc may include the third light emitting device EDc.

Referring to FIG. 4, the display panel 110 according to implementations of the present disclosure may include a plurality of row lines RL and a plurality of column lines CL.

Each of the plurality of row lines RL may extend in a row direction. The plurality of row lines RL may be electrically connected to a first electrode of each of the plurality of light emitting devices ED.

Each of the plurality of column lines CL may extend in a column direction. The plurality of column lines CL may be electrically connected to a second electrode of each of the plurality of light emitting devices ED.

For example, the first electrode of each of the plurality of light emitting devices ED may be an anode, and the second electrode of each of the plurality of light emitting devices ED may be a cathode. For another example, the first electrode of each of the plurality of light emitting devices ED may be a cathode, and the second electrode of each of the plurality of light emitting devices ED may be an anode.

Each of the plurality of row lines RL may be electrically connected to the second electrode of each of the plurality of light emitting devices ED. That is, the second electrode of each of the plurality of light emitting devices ED may be connected in common to one row line RL.

Each of the plurality of column lines CL may be electrically connected to the first electrode of each of the plurality of light emitting devices ED. That is, the first electrode of each of the plurality of light emitting devices ED may be connected in common to one column line CL.

Referring to FIG. 4, a width of each of the plurality of row lines RL may be greater than a width of each of the plurality of column lines CL.

Referring to FIG. 4, the display panel 110 according to implementations of the present disclosure may include the plurality of drivers DRV. The plurality of drivers DRV may drive the plurality of light emitting devices ED, the plurality of column lines CL, and the plurality of row lines RL.

The plurality of drivers DRV may be embedded in the display panel 110. The plurality of drivers DRV may be disposed in the display area DA, and may be disposed on the substrate 210.

The plurality of drivers DRV may be disposed to correspond to the plurality of unit driving areas UDA. That is, one driver DRV may be disposed in one unit driving area UDA.

Each of the plurality of drivers DRV may drive the plurality of row lines RL and the plurality of column lines CL disposed in the corresponding unit driving area UDA among the plurality of unit driving areas UDA. Accordingly, the plurality of light emitting devices ED disposed in the corresponding unit driving area UDA may emit light.

The plurality of drivers DRV may be disposed in the display area DA and may be positioned closer to the substrate 210 than the plurality of light emitting devices ED.

For example, the plurality of row lines RL may be driven sequentially. For another example, the plurality of row lines RL may be driven simultaneously. For another example, two or more of the plurality of row lines RL may be driven simultaneously.

For example, during any one display driving period, among the plurality of row lines RL arranged in the unit driving area UDA, at least one row line RL may be driven, and the remaining row lines RL may not be driven.

According to implementations of the present disclosure, a voltage applied to the row line RL may be referred to as a low potential voltage, and the low potential voltage may be referred to as a row line voltage or a cathode voltage. The low potential voltage may have various voltage values according to a driving type or a driving state. For example, the low potential voltage may include a first low potential voltage, a second low potential voltage, and a third low potential voltage.

Driving of the row line RL may mean that the first low potential voltage is supplied to the row line RL. Not driving of the row line RL may mean that the second low potential voltage higher than the first low potential voltage is supplied to the row line RL. Accordingly, the light emitting devices ED overlapping the driven row line RL may emit light, and the light emitting devices ED overlapping the non-driving row line RL may not emit light.

For example, any first row line RL among the plurality of row lines RL may receive the first low potential voltage during a first period, and may receive the second low potential voltage higher than the first low potential voltage during a second period different from the first period. Accordingly, the light emitting devices ED overlapping the first row line RL may emit light during the first period and may not emit light during the second period different from the first period. For example, the first period and the second period may be included in one display driving period. For another example, the first period and the second period may be included in different display driving periods.

A structure of one unit driving area UDA will be described in more detail with reference to FIG. 4.

Referring to FIG. 4, for example, one unit driving area UDA may be divided into a first sub-driving area SDA1 and a second sub-driving area SDA2. As another example, one unit driving area UDA may be divided into three or more sub-driving areas. As another example, one unit driving area UDA may not be divided into two or more sub-driving areas.

Referring to FIG. 4, one unit driving area UDA includes one driver DRV and (2n×m) pixels P(1, 1) to P(2n, m) driven by one driver DRV.

In implementations of the present disclosure, n may be a sequence number of a row, the number of rows in each of the first sub-driving areas SDA1 and the second sub-driving areas SDA2, the number of row lines RL in each of the first sub-driving areas SDA1 and the second sub-driving areas SDA2, or the number of pixel rows in each of the first sub-driving areas SDA1 and the second sub-driving areas SDA2. m may be a sequence number of columns, the number of columns in each of the first sub-driving areas SDA1 and the second sub-driving areas SDA2, the number of column lines CL in each of the first sub-driving areas SDA1 and the second sub-driving areas SDA2, or the number of pixel columns in each of the first sub-driving areas SDA1 and the second sub-driving areas SDA2.

In implementations of the present disclosure, n may be a natural number of 1 or more, and m may be a natural number of 1 or more.

Referring to FIGS. 4, (2n×m) pixels P(1, 1) to P(2n, m) may be arranged in 2n rows R(1) to R(2n) and m columns C(1) to C(m).

Among (2n×m) pixels P(1, 1) to P(2n, m), (n×m) pixels arranged in the first to nth rows R(1) to R(n) may be disposed in the first sub-driving area SDA1.

Among (2n×m) pixels P(1, 1) to P(2n, m), pixels arranged in the (n+1)th to 2nth rows R(n+1) to R(2n) may be disposed in the second sub-driving area SDA2.

Referring to FIG. 4, one unit driving area UDA may include 2n row lines RL(1) to RL(2n) to drive (2n×m) pixels P(1,1) to P(2n, m).

Among 2n row lines RL(1) to RL(2n), the first to nth row lines RL(1) to RL(n) may disposed in the first sub-driving area SDA1. Among 2n row lines RL(1) to RL(2n), the (n+1)th to 2nth row lines RL(n+1) to RL(2n) may disposed in the second sub-driving area SDA2.

Each of the 2n row lines RL(1) to RL(2n) may overlap m pixels. For example, the first row line RL(1) may overlap m pixels P(1, 1) to P(1, m) arranged in the first row R(1). The nth row line RL(n) may overlap m pixels P(n, 1) to P(n, m) arranged in the nth row R(n). The (n+1)th row line RL(n+1) may overlap m pixels P(n+1, 1) to P(n+1, m) arranged in the (n+1)th row R(n+1). The 2nth row line RL(2n) may overlap m pixels P(2n, 1) to P(2n, m) arranged in the 2nth row R(2n).

For example, the first row line R(1) may be connected to k subpixels SPa, SPb and SPc included in each of m pixels P(1,1) to P(1, m) arranged in the first row R(1). More specifically, the first row line R(1) may be connected to the second electrodes of k subpixels SPa, SPb and SPc included in each of m pixels P(1,1) to P(1, m) arranged in the first row R(1).

For example, the nth row line R(n) may be connected to k subpixels SPa, SPb and SPc included in each of m pixels P(n,1) to P(n, m) arranged in the nth row R(n). More specifically, the nth row line R(n) may be connected to the first electrodes of k subpixels SPa, SPb and SPc included in each of m pixels P(n,1) to P(n, m) arranged in the nth row R(n).

For example, the (n+1)th row line R(n+1) may be connected to k subpixels SPa, SPb and SPc included in each of m pixels P(n+1,1) to P(n+1, m) arranged in the (n+1)th row R(n+1). More specifically, the (n+1)th row line R(n+1) may be connected to the first electrodes of k subpixels SPa, SPb and SPc included in each of m pixels P(n+1,1) to P(n+1, m) arranged in the (n+1)th row R(n+1).

For example, the 2nth row line R(2n) may be connected to k subpixels SPa, SPb and SPc included in each of m pixels P(2n,1) to P(2n, m) arranged in the 2nth row R(2n). More specifically, the 2nth row line R(2n) may be connected to the first electrodes of k subpixels SPa, SPb and SPc included in each of m pixels P(2n,1) to P(2n, m) arranged in the 2nth row R(2n).

Referring to FIG. 4, one unit driving area UDA may include (m×k×2) column lines CL to drive (2n×m) pixels P(1, 1) to P(2n, m). Here, k denotes the number of subpixels SP included in one pixel P. In the example of FIG. 4, k is 3. That is, one pixel P may include three subpixels SPa, SPb, and SPc.

The first sub-driving area SDA1 may include (m×k×2) column lines CL to drive (n×m) pixels P(1, 1) to P(n, m). In the example of FIG. 4, k is 3. That is, the first sub-driving area SDA1 may include 3m column lines CL.

In the first sub-driving area SDA1, k column lines CLa, CLb, and CLb may be disposed in each of m columns C(1) to C(m). In the example of FIG. 4, k is 3. In the first sub-driving area SDA1, m columns C(1) to C(m) may include three column lines CLa, CLb, and CLc.

In each of m columns C(1) to C(m), each of k column lines CL may be connected in common with n pixels arranged in a corresponding column. In each of m columns C(1) to C(m), each of k column lines CL may be connected in common with the first electrode of n light emitting devices arranged in a corresponding column. In the example of FIG. 4, k is 3. In each of m columns C(1) to C(m), the three column lines CLa, CLb, and CLc may be connected to the first electrodes of 3n light emitting devices ED included in the n pixels arranged in the corresponding column. For example, in each of m columns C(1) to C(m), the first column line CLa may be connected to the first electrodes of n first light emitting devices EDa included in the n pixels arranged in the corresponding column. In each of m columns C(1) to C(m), the second column line CLb may be connected to the first electrodes of n second light emitting devices EDb included in the n pixels arranged in the corresponding column. In each of m columns C(1) to C(m), the third column line CLc may be connected to the first electrodes of n third light emitting devices EDc included in the n pixels arranged in the corresponding column.

The second sub-driving area SDA2 may include (m×k) column lines CL to drive (n×m) pixels P(n+1, 1) to P(2n, m). In the example of FIG. 4, k is 3. That is, the second sub-driving area SDA2 may include 3m column lines CL.

In the second sub-driving area SDA2, k column lines may be disposed in each of m columns C(1) to C(m). In the example of FIG. 4, k is 3. In the second sub-driving area SDA2, m columns C(1) to C(m) may include three column lines CLa, CLb, and CLc.

In each of m columns C(1) to C(m), each of k column lines CL may be connected in common with n pixels arranged in a corresponding column. In each of m columns C(1) to C(m), each of k column lines CL may be connected in common with the first electrode of n light emitting devices arranged in a corresponding column. In the example of FIG. 4, k is 3. In each of m columns C(1) to C(m), the three column lines CLa, CLb, and CLc may be connected to the first electrodes of 3n light emitting devices ED included in the n pixels arranged in the corresponding column. For example, in each of m columns C(1) to C(m), the first column line CLa may be connected to the first electrodes of n first light emitting devices EDa included in the n pixels arranged in the corresponding column. In each of m columns C(1) to C(m), the second column line CLb may be connected to the first electrodes of n second light emitting devices EDb included in the n pixels arranged in the corresponding column. In each of m columns C(1) to C(m), the third column line CLc may be connected to the first electrodes of n third light emitting devices EDc included in the n pixels arranged in the corresponding column.

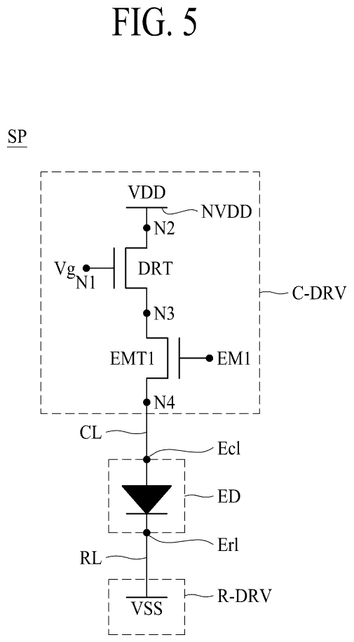

FIG. 5 is a diagram schematically illustrating a structure of the subpixel SP of a display panel according to implementations of the present disclosure.

Referring to FIG. 5, the sub-pixel SP according to implementations of the present disclosure may include a light emitting device ED including a first electrode Ecl and a second electrode Erl, a column driver C-DRV for driving the column line CL electrically connected to the first electrode Ecl of the light emitting device ED, and a row driver R-DRV for driving the row line RL electrically connected to the second electrode Erl of the light emitting device ED.

Referring to FIG. 5, the light emitting device ED may include the first electrode Ecl and the second electrode Erl. The first electrode Ecl may be electrically connected to the column line CL, and the second electrode Erl may be electrically connected to the row line RL. For example, the first electrode Ecl may be an anode, and the second electrode Erl may be a cathode. For another example, the first electrode Ecl may be a cathode, and the second electrode Erl may be an anode.

Referring to FIG. 5, the column driver C-DRV included in the unit driving area UDA may be connected to the plurality of column lines CL included in the unit driving area UDA, and may drive the plurality of column lines CL included in the unit driving area UDA. Each of the plurality of column lines CL may be connected in common to the first electrode Ecl of each of the plurality of light emitting devices ED included in the plurality of subpixels SP arranged in the corresponding column.

Referring to FIG. 5, the row driver R-DRV included in the unit driving area UDA may be connected to the plurality of row lines RL included in the unit driving area UDA, and may drive the plurality of row lines RL included in the unit driving area UDA. Each of the plurality of row lines RL may be connected in common to the second electrode Erl of each of the plurality of light emitting devices ED included in the plurality of subpixels SP arranged in the corresponding row.

Referring to FIG. 5, the column driver C-DRV may include main nodes including a first node N1, a second node N2, a third node N3, and a fourth node N4. The column driver C-DRV may include a driving transistor DRT and a first emission control transistor EMT1.

The first node N1 may be a node to which a voltage Vg for controlling the on/off of the driving transistor DRT is applied. The second node N2 may be a node electrically connected to a high potential voltage node NVDD to which a high potential voltage VDD is applied. The third node N3 may be a node to which the driving transistor DRT and the first emission control transistor EMT1 are connected. The fourth node N4 may be a node to which the first emission control transistor EMT1 and the light emitting device ED are electrically connected, and may be a node to which the column line CL is electrically connected. Here, a source electrode or a drain electrode of the first emission control transistor EMT1 and the first electrode Ecl of the light emitting device ED may be commonly connected to the column line CL.

The driving transistor DRT may supply a driving current for emitting the light emitting device ED, is connected between the second node N2 and the third node N3, and may control the connection between the second node N2 and the third node N3 according to a voltage of the first node N1.

A gate electrode of the driving transistor DRT may be electrically connected to the first node N1, and a gate voltage Vg may be applied. The drain electrode or the source electrode of the driving transistor DRT may be electrically connected to the second node N2. The source electrode or the drain electrode of the driving transistor DRT may be electrically connected to the third node N3.

The first emission control transistor EMT1 may control whether a path through which the driving current flows is connected, and may control whether the light emitting device ED emits light.

When the driving transistor DRT and the first light emission control transistor EMT1 are turned on between the high potential voltage VDD and the low potential voltage VSS, the driving current may be supplied to the light emitting device ED through the driving transistor DRT and the first light emission control transistor EMT1. Accordingly, the light emitting device ED may emit light.

The first emission control transistor EMT1 is connected between the third node N3 and the fourth node N4, and the connection between the third node N3 and the fourth node N4 may be controlled according to a first emission control signal EM1. The first emission control signal EM1 may be applied to a gate electrode of the first emission control transistor EMT1. A drain electrode or a source electrode of the first emission control transistor EMT1 may be electrically connected to the third node N3. The source electrode or the drain electrode of the first emission control transistor EMT1 may be electrically connected to the fourth node N4.

The first emission control signal EM1 may be a pulse width modulation signal that changes every predefined time (e.g., each frame, or each subframe included in one frame), but implementations of the present disclosure are not limited thereto.

The first emission control signal EM1 may be generated by the driver DRV or supplied to the driver DRV from a driving-related circuit such as a timing controller.

Referring to FIG. 5, the row driver R-DRV may drive at least one row line RL by supplying the low potential voltage VSS to at least one row line RL.

The row driver R-DRV may perform display-on driving or display-off driving for one row line RL.

The row driver R-DRV may supply a low potential voltage for display-on driving to one row line RL in order to perform display-on driving for one row line RL. The row driver R-DRV may supply a low potential voltage for display-off driving to one row line RL in order to perform display-off driving for one row line RL.

The low potential voltage for display-on driving and the low potential voltage for display-off driving may be different. For example, the low potential voltage for display-on driving may be lower than the low potential voltage for display-off driving. In implementations of the present disclosure, the “low potential voltage for display-on driving” is referred to as a “first low potential voltage,” and the “low potential voltage for display-off driving” is referred to as a “second low potential voltage.”

Referring to FIG. 5, the column driver C-DRV may further include at least one switching element and/or at least one transistor in addition to the driving transistor DRT and the first light emission control transistor EMT1. Each of all transistors included in the column driver C-DRV may be an n-type transistor or a p-type transistor.

The column driver C-DRV may further include at least one capacitor.

The column driver C-DRV may further include at least one circuit element. For example, at least one circuit element may include a power output buffer.

Referring to FIG. 5, the row driver R-DRV may include at least one switching element and/or at least one transistor. Each of all transistors included in the row driver R-DRV may be an n-type transistor or a p-type transistor.

The row driver R-DRV may further include at least one circuit element. For example, at least one circuit element may include a power output buffer.

Referring to FIG. 5, the column driver C-DRV and the row driver R-DRV may be internal circuits included in the driver DRV. As another example, the column driver C-DRV and the row driver R-DRV may be circuits that are not included in the driver DRV and are formed on the substrate 210 of the display panel 110.

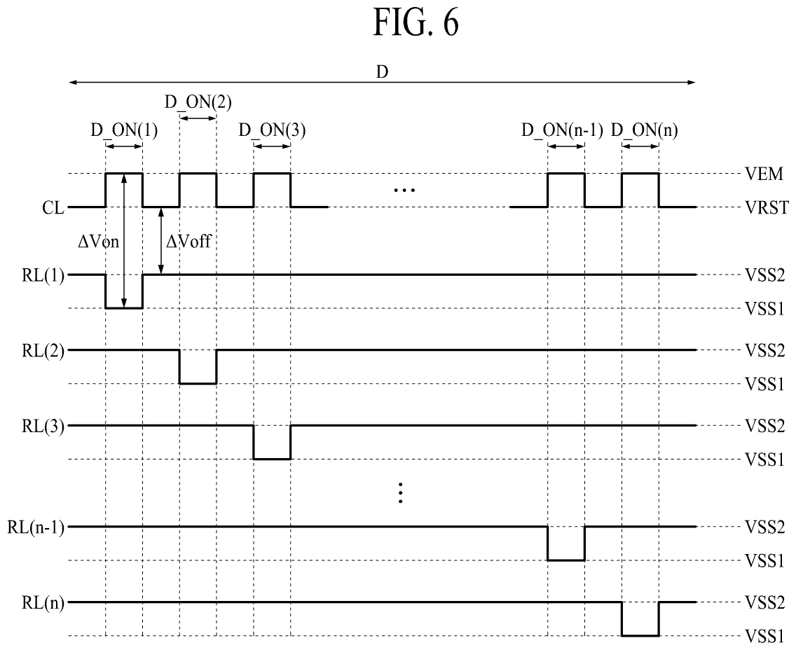

FIG. 6 illustrates a driving timing diagram of n row lines RL(n) and one column line CL included in the first sub-driving area SDA1 of the display panel 110 according to implementations of the present disclosure.

The row driver R-DRV of the driver DRV may drive the n row lines RL(1) to RL(n) disposed in the first sub-driving area SDA1.

The driving for each of the n row lines RL(1) to RL(n) arranged in the first sub-driving area SDA1 may include a display-on driving for emitting the light emitting devices ED arranged in each of the n row lines RL(1) to RL(n) and a display-off driving for not emitting the light emitting devices ED arranged in each of the n row lines RL(1) to RL(n).

Regarding a driving sequence for each of the n row lines RL(1) to RL(n) disposed in the first sub-driving area SDA1, the following methods may be exemplified.

For example, the display-on driving for each of the plurality of row lines RL may be sequentially performed. As another example, the display-on driving for each of the plurality of row lines RL may be performed simultaneously. As another example, the display-on driving for each of two or more row lines RL among the plurality of row lines RL may be performed simultaneously. Hereinafter, for convenience of description, a case where the display-on driving for each of the plurality of row lines RL is sequentially performed will be described as an example. However, the present disclosure is not limited thereto.

The row driver R-DRV of the driver DRV may sequentially drive the n row lines RL(1) to RL(n) disposed in the first sub-driving area SDA1. That is, the display-on driving periods D_ON(1) to D_ON(n) for the n row lines RL(1) to RL(n) disposed in the first sub-driving area SDA1 may be sequential.

Based on any one row line RL among the n row lines RL(1) to RL(n) disposed in the first sub-driving area SDA1, the display-on driving period D_ON(1) for the corresponding row line RL may exist at least once during the display driving period D. During the display driving period D, all remaining times except for the display-on driving period D_ON(1) for the corresponding row line RL may be the display-off driving period.

Referring to FIG. 6, during any one display driving period D, among the n row lines RL(1) to RL(n) arranged in the unit driving area UDA, display-on driving may be performed for at least one row line RL, and display-off driving may be performed without performing display-on driving for the remaining row lines RL.

For example, during any one display driving period (D), among the n row lines RL(1) to RL(n) arranged in the unit driving area UDA, display-on driving may be performed for a first row line RL(1) and display-off driving may be performed without performing display-on driving for the second to nth row lines RL(2) to RL(n).

For another example, during any one display driving period D, among the n row lines RL(1) to RL(n) arranged in the unit driving area UDA, display-on driving may be performed for the second row line RL(2), and display-off driving may be performed without performing display-on driving for the first row line RL(1) and third to nth row lines RL(3) to RL(n).

For another example, during any one display driving period D, among the n row lines RL(1) to RL(n) arranged in the unit driving area UDA, display-on driving may be performed for the third row line RL(3), and display-off driving may be performed without performing display-on driving for the first row line RL(1), the second row line RL(2) and fourth to nth row lines RL(4) to RL(n).

For another example, during any one display driving period D, among the n row lines RL(1) to RL(n) arranged in the unit driving area UDA, display-on driving may be performed for the (n−1)th row line RL(n−1), and display-off driving may be performed without performing display-on driving for the first to (n−2)th row line RL(1) to RL(n−2) and nth row line RL(n).

For another example, during any one display driving period D, among the n row lines RL(1) to RL(n) arranged in the unit driving area UDA, display-on driving may be performed for the nth row line RL(n), and display-off driving may be performed without performing display-on driving for the first to the (n−1)th row line RL(1) to RL(n−1).

Referring to FIG. 6, the display-on driving of any one of the n row lines RL(1) to RL(n) disposed in the unit driving area UDA may mean that the first low potential voltage VSS1 having a predefined level is supplied to the corresponding row line RL. When the display-on driving is performed on any row line RL, the light emitting devices ED arranged corresponding to the corresponding row line RL may emit light.

When the display-on driving is not performed on any of the n row lines RL(1) to RL(n) disposed in the unit driving area UDA and the display-off driving is performed, it may mean that the second low potential voltage VSS2 having a predefined level is supplied to the corresponding row line RL. When the display-off driving is performed on any row line RL, the light emitting devices ED arranged corresponding to the corresponding row line RL may not emit light.

The first low potential voltage VSS1 may be the low potential voltage VSS for display-on driving, and the second low potential voltage VSS2 may be the low potential voltage VSS for display-off driving. The second low potential voltage VSS2 may be higher than the first low potential voltage VSS1.

Referring to FIG. 6, any one of the n row lines RL(1) to RL(n) arranged in the unit driving area UDA may receive the first low potential voltage VSS1 during a first period, and the second low potential voltage VSS2 which is higher than the first low potential voltage VSS1 may be supplied during a second period different from the first period. For example, the first period and the second period may be included in one display driving period D. For another example, the first period and the second period may be included in different display driving periods D.

For example, among the n row lines RL(1) to RL(n) arranged in the unit driving area UDA, the first row line RL(1) may receive the first low potential voltage VSS1 during a first display-on driving period D_ON(1) and may receive the second low potential voltage VSS2 which is higher than the first low potential voltage VSS1 during a second display-on driving period D_ON(2) different from the first display-on driving period D_ON(1).

For example, during the first display-on driving period D_ON(1), the first row line RL(1) may receive the first low potential voltage VSS1, and the second to nth row lines RL(2) to RL(n) may receive the second low potential voltage VSS2. During the second display-on driving period D_ON(2), the second row line RL(2) may receive the first low potential voltage VSS1, and the first row line RL(1) and the third to nth row lines RL(3) to RL(n) may receive the second low potential voltage VSS2.

For example, during the first display-on driving period D_ON(1), a plurality of light emitting devices ED arranged in the first row overlapping the first row line RL(1) may emit light, and a plurality of light emitting devices ED arranged in the second to nth row overlapping the second to nth rows RL(2) to RL(n) may not emit light. During the second display-on driving period D_ON(2), a plurality of light emitting devices ED arranged in the second row overlapping the second row line RL(1) may emit light, and a plurality of light emitting devices ED arranged in the first row and the third to nth row overlapping the first row line RL(1) and the third to nth row lines RL(3) to RL(n) may not emit light.

For example, the first display-on driving period D_ON(1) and the second display-on driving periods D_ON(2) may be included in one display driving period D. For another example, the first display-on driving period D_ON(1) and the second display-on driving period D_ON(2) may be included in different display driving periods D.

Referring to FIG. 6, (m×k) column lines CL may be disposed in the unit driving area UDA. In the unit driving area UDA, (m×k) column lines CL may cross n row lines RL(1) to RL(n). The column lines CL shown in FIG. 6 may be one of (m×k) column lines CL.

During the display driving period D, each of the (m×k) column lines CL intersecting the n row lines RL(1) to RL(n) may be synchronized with display-on driving period D_ON(1) to D_ON(n) of each of the n row lines RL(1) to RL(n), and a display voltage VEM required to emit light of the corresponding light emitting device ED may be applied. Here, the display voltage VEM is also referred to as an emission driving voltage.

During the display driving period D, a reset voltage VRST may be applied to each of the (m×k) column lines CL intersecting the n row lines RL(1) to RL(n) for all remaining time except for the display-on driving periods D_ON(1) to D_ON(n) of each of the n row lines RL(1) to RL(n).

The display voltage VEM may be a voltage that varies according to a constant voltage or an image signal. The reset voltage VRST may be a voltage lower than the display voltage VEM and may be a constant voltage or a variable voltage.

During the display driving period D, during the display-on driving period D_ON(1) to D_ON(n) of each of the n row lines RL(1) to RL(n), a voltage difference VEM-VSS1 between the display voltage VEM applied to the corresponding column line CL and the first low potential voltage VSS1 applied to the corresponding row line RL may be a display-on voltage ΔVon.

The light emitting device ED may be connected between the corresponding column line CL and the corresponding row line RL. The display voltage VEM and the first low potential voltage VSS1 may be applied to the first electrode Ecl and the second electrode Erl of the light emitting device ED, respectively.

The display-on voltage ΔVon is a voltage difference between the first electrode Ecl and the second electrode Erl of the corresponding light emitting device ED, and may be a voltage capable of emitting light of the corresponding light emitting device ED. For example, the display-on voltage ΔVon may be greater than or equal to a threshold voltage, which is an intrinsic characteristic value of the corresponding light emitting device ED.

A voltage difference VRST-VSS2 between the reset voltage VRST applied to the corresponding column line CL and the second low potential voltage VSS2 applied to the corresponding row line RL may be a display-off voltage ΔVoff during all remaining time except for the display-on driving periods D_ON(1) to D_ON(n) of each of the n row lines RL(1) to RL(n).

The light emitting device ED may be connected between the corresponding column line CL and the corresponding row line RL. The reset voltage VRST and the second low potential voltage VSS2 may be applied to the first electrode Ecl and the second electrode Erl of the light emitting device ED, respectively.

The display-off voltage ΔVoff is a voltage difference between the first electrode Ecl and the second electrode Erl of the corresponding light emitting device ED, and may be a voltage that cannot emit light of the corresponding light emitting device ED. For example, the display-off voltage ΔVoff may be less than a threshold voltage, which is an intrinsic characteristic value of the corresponding light emitting device ED. That is, the display-on voltage ΔVon may be greater than or equal to the display-off voltage ΔVoff.

Hereinafter, a circuit for driving the n light emitting devices ED(1) to ED(n) connected to one column line CL in the display panel 110 according to the implementations of the present disclosure will be described in more detail.

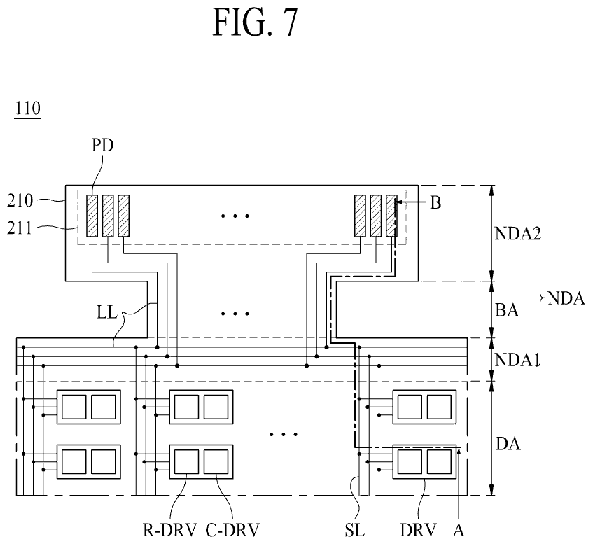

FIG. 7 is a plan view of a display panel according to implementations of the present disclosure.

Referring to FIG. 7, the substrate 210 of the display panel 110 according to implementations of the present disclosure may include a display area DA and a non-display area NDA, and the non-display area NDA may include a first non-display area NDA1, a bending area BA, and a second non-display area NDA2.

Referring to FIG. 7, the plurality of drivers DRV may be disposed in the display area DA. Each of the plurality of drivers DRV may be a circuit for driving light emitting devices of the plurality of subpixels included in the corresponding unit driving area UDA of FIG. 4. Each of the plurality of drivers DRV may include the row driver R-DRV for driving the plurality of row lines and the column driver C-DRV for driving the plurality of column lines in order to drive the plurality of light emitting devices ED included in the corresponding unit driving area UDA of FIG. 4.

Referring to FIG. 7, a pad part 211 including a plurality of pads PD may be disposed in the second non-display area NDA2.

Referring to FIG. 7, a plurality of signal lines SL and a plurality of link lines LL for signal transmission between the plurality of drivers DRV and the pad part 211 disposed in the display area DA may be disposed on the substrate 210. The plurality of signal lines SL may be electrically connected between the plurality of link lines LL and the plurality of drivers DRV. The plurality of link lines LL may electrically connect the plurality of pads PD to the plurality of signal lines SL.

Referring to FIG. 7, the plurality of link lines LL may be disposed in the non-display area NDA, and all or a part of each of the plurality of signal lines SL may be disposed in the display area DA.

Each of the plurality of drivers DRV may receive various signals to perform a driving operation through the plurality of link lines LL and the plurality of signal lines SL. Here, the various signals may include various power voltages and various signals required for a driving operation of each of the plurality of drivers DRV.

As the bending area BA is bent, a portion of the plurality of link lines LL may also be bent. Stress is concentrated on a portion of the bent link line LL, and thus, a crack may be generated in the link line LL. Accordingly, the plurality of link lines LL may be formed of a conductive material having excellent ductility in order to reduce cracks when the bending area BA is bent. For example, the plurality of link lines LL may be formed of a conductive material having excellent ductility, such as gold (Au), silver (Ag), or aluminum (Al), but implementations of the present disclosure are not limited thereto. In addition, the plurality of link lines LL may be formed of one of various conductive materials used in the display area DA. For example, the plurality of link lines LL may be formed of molybdenum (Mo), chromium (Cr), titanium (Ti), nickel (Ni), neodymium (Nd), copper (Cu), silver (Ag) and magnesium (Mg), or an alloy thereof, or the like, but implementations of the present disclosure are not limited thereto. The plurality of link lines LL may be configured in a multilayer structure including various conductive materials. For example, the plurality of link lines LL may be composed of a triple layer structure of titanium (Ti)/aluminum (Al)/titanium (Ti), but implementations of the present disclosure are not limited thereto.

The plurality of link lines LL may be configured in various shapes to reduce stress. At least a portion of the plurality of link lines LL disposed on the bending area BA may extend in the same direction as a extending direction of the bending area BA, or may extend in a direction different from the extending direction of the bending area BA to reduce stress. For example, when the bending area BA extends in one direction from the first non-display area NDA1 to the second non-display area NDA2, at least a portion of the link line LL disposed on the bending area BA may extend in a direction inclined to the one direction. For another example, at least a portion of the plurality of link lines LL may be configured in pattern having various shape. For example, at least a portion of the plurality of link lines LL disposed on the bending area BA may have a shape in which a conductive pattern having at least one of a diamond shape, a rhombus shape, a trapezoidal shape, a triangular wave shape, a sawtooth wave shape, a sinusoidal wave shape, a circular wave shape, and an omega shape is repeatedly arranged, but implementations of the present disclosure are not limited thereto. Therefore, in order to reduce or minimize the stress concentrated on the plurality of link lines LL and the corresponding crack, the shape of the plurality of link lines LL may be formed in various shapes including the above-described shape, but implementations of the present disclosure are not limited thereto.

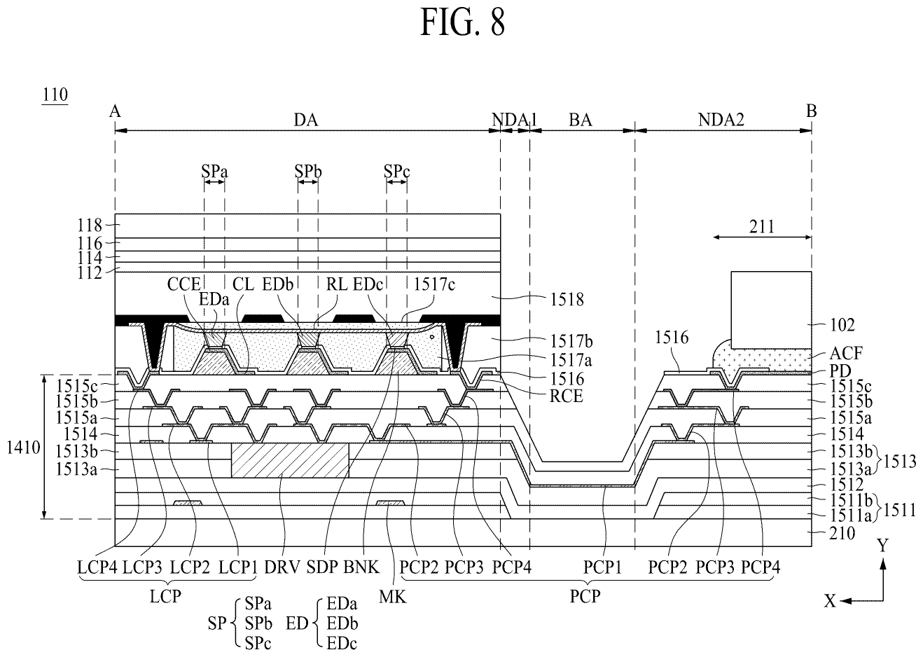

FIG. 8 is a detailed cross-sectional view of a display panel 110 according to implementations of the present disclosure, and is a cross-sectional view taken along line A-B of FIG. 7.

FIG. 8 is an enlarged cross-sectional view of a sub-pixel SP of the display panel 110 according to implementations of the present specification. FIG. 8 is a cross-sectional view of the display area DA, the first non-display area NDA, the bending area BA, and the second non-display area NDA2.

Meanwhile, for convenience of the showing, FIG. 7 shows that the A-B line does not overlap the signal line SL and the link line LL, but the A-B line in FIG. 7 is intended to display the same or substantially same location as the adjacent signal line SL and the link line LL.

Referring to FIG. 8, a buffer layer 1511 may be disposed on a substrate 210. The buffer layer 1511 may include a first buffer layer 1511a and a second buffer layer 1511b. The first buffer layer 1511a and the second buffer layer 1511b may be disposed in the display area DA, the first non-display area NDA1, and the second non-display area NDA2, and may not be disposed in the whole or a part of the bending area BA. However, the present disclosure is not limited thereto.

The first buffer layer 1511a and the second buffer layer 1511b may reduce penetration of moisture or impurities through the substrate 210. The first buffer layer 1511a and the second buffer layer 1511b may be formed of an inorganic insulating material. For example, the first buffer layer 1511a and the second buffer layer 1511b may be formed of a single layer or a multilayer of silicon oxide (SiOx) or silicon nitride (SiNx), but implementations of the present disclosure are not limited thereto.

For example, portions of the first buffer layer 1511a and the second buffer layer 1511b on the bending area BA may be removed. An upper surface of the substrate 210 located in the bending area BA may be exposed by an area (opening) from which the first buffer layer 1511a and the second buffer layer 1511b are removed.

By removing the first buffer layer 1511a and the second buffer layer 1511b from the bending area BA, cracks in the first buffer layer 1511a and the second buffer layer 1511b that may occur during bending may be reduced or minimized.

A plurality of alignment keys MK may be disposed between the first buffer layer 1511a and the second buffer layer 1511b. The plurality of alignment keys MK may identify a position of the driver DRV during a manufacturing process of the display panel 110. For example, the plurality of alignment keys MK may align the position of the driver DRV transferred onto an adhesive layer 1512. For another example, the plurality of alignment keys MK may be omitted.

An adhesive layer 1512 may be disposed on the second buffer layer 1511b. The adhesive layer 1512 may be disposed in the display area DA, the first non-display area NDA1, the bending area BA, and the second non-display area NDA2. For another example, at least a portion of the adhesive layer 1512 may be removed from the non-display area NDA including the bending area BA. For example, the adhesive layer 1512 may be formed of any one of an adhesive polymer, an epoxy resin, a UV curable resin, a polyimide-based material, an acrylate-based material, a urethane-based material, and a polydimethylsiloxane (PDMS), but implementations of the present disclosure are not limited thereto.

The driver DRV may be disposed on the adhesive layer 1512 in the display area DA. When the driver DRV is implemented as a driving chip (driving integrated circuit), the driving driver may be mounted on the adhesive layer 1512 by a transfer process, but implementations of the present disclosure are not limited thereto.

The display panel 110 may further include a side protective layer 1513 disposed on side surfaces of the plurality of drivers DRV, and an upper protective layer 1514 disposed on the plurality of drivers DRV and the side protective layer 1513. For example, the side protective layer 1513 may include at least one of a first protective layer 1513a and a second protective layer 1513b disposed on the side surfaces of the plurality of drivers DRV, and in some cases, may further include at least one additional protective layer. The first protective layer 1513a and the second protective layer 1513b may be disposed on the adhesive layer 1512. The first protective layer 1513a and the second protective layer 1513b may surround the side surfaces of the driver DRV, but implementations of the present disclosure are not limited thereto. For example, the second protective layer 1513b may be disposed to cover at least a portion of the upper surface of the driver DRV. For example, at least one of the first protective layer 1513a and the second protective layer 1513b disposed on the bending area BA may be omitted. For example, the first protective layer 1513a may be entirely disposed in the display area DA and the non-display area NDA, and the second protective layer 1513b may be partially disposed in the display area DA, the first non-display area NDA1, and the second non-display area NDA2. For example, in all or a portion of the bending area BA, at least a portion of the second protective layer 1513b may be removed. However, implementations of the present disclosure are not limited thereto.

For example, the side protective layer 1513 including at least one of the first protective layer 1513a and the second protective layer 1513b may be formed of an organic insulating material (organic layer), but implementations of the present disclosure are not limited thereto. For example, the first protective layer 1513a and the second protective layer 1513b may be formed of a photo resist, polyimide (PI), a photo acryl-based material, or the like, but implementations of the present disclosure are not limited thereto. For example, the first protective layer 1513a and the second protective layer 1513b may be an overcoating layer or an insulating layer, but implementations of the present disclosure are not limited thereto.

According to implementations of the present disclosure, a plurality of line connection patterns LCP may be disposed on the second protective layer 1513b in the display area DA. The plurality of line connection patterns LCP may be wires for electrically connecting the driver DRV to other elements. For example, the driver DRV may be electrically connected to the plurality of column lines CL, the plurality of row lines RL, a plurality of row connection electrodes RCE, and the like through the plurality of line connection patterns LCP.

For example, the plurality of line connection patterns LCP may include a first line connection pattern LCP1, a second line connection pattern LCP2, a third line connection pattern LCP3, and a fourth line connection pattern LCP4, but implementations of the present disclosure are not limited thereto. For example, the first line connection pattern LCP1, the second line connection pattern LCP2, the third line connection pattern LCP3, and the fourth line connection pattern LCP4 may be disposed in different metal layers.

For example, the plurality of first line connection patterns LCP1 may be disposed on the second protective layer 1513b. The plurality of first line connection patterns LCP1 may be electrically connected to the driver DRV. The plurality of first line connection patterns LCP1 may transfer a voltage output from the driver DRV to the column line CL or the row line RL.

The display panel 110 may further include a side protective layer 1513 including at least one of the first protective layer 1513a and the second protective layer 1513b and an upper protective layer 1514 disposed on the plurality of drivers DRVs. For example, the upper protective layer 1514 may include the third protective layer 1514, and in some cases, may further include at least one additional protective layer. The third protective layer 1514 may be disposed on the second protective layer 1513b and the plurality of first line connection patterns LCP1. The third protective layer 1514 may be entirely disposed in the display area DA and the non-display area NDA. In the bending area BA, the third protective layer 1514 may cover a side surface of the second protective layer 1513b and an upper surface of the first protective layer 1513a.

For example, the third protective layer 1514 may be formed of an organic insulating material. For example, the third protective layer 1514 may be formed of a photo resist, polyimide (PI), a photoacryl-based material, or the like, but implementations of the present disclosure are not limited thereto. For example, the first protective layer 1513a, the second protective layer 1513b, and the third protective layer 1514 may be formed of the same or substantially same insulating material, or at least one of the first protective layer 1513a, the second protective layer 1513b, and the third protective layer 1514 may be formed of an insulating material different from the rest. Implementations of the present disclosure are not limited thereto.

A plurality of second line connection patterns LCP2 may be disposed on the third protective layer 1514. The plurality of second line connection patterns LCP2 may be electrically connected to or directly connected to the driver DRV. For example, a portion of the second line connection pattern LCP2 may be directly or indirectly connected to the driver DRV through a contact hole of the third protective layer 1514. The other portion of the second line connection pattern LCP2 may be electrically connected to the first line connection pattern LCP1 through a contact hole of the third protective layer 1514. However, implementations of the present disclosure are not limited thereto. The voltage output from the driver DRV may be transferred to the column line CL or the row line RL through a connection pattern different from that of the plurality of second line connection patterns LCP2.

A first insulating layer 1515a may be disposed on the plurality of second line connection patterns LCP2. The first insulating layer 1515a may be disposed entirely in the display area DA and the non-display area NDA, but implementations of the present disclosure are not limited thereto. The first insulating layer 1515a may be formed of an organic insulating material, but implementations of the present disclosure are not limited thereto. For example, the first insulating layer 1515a may be formed of a photo resist, polyimide (PI), a photoacryl-based material, or the like, but implementations of the present disclosure are not limited thereto.

A plurality of third line connection patterns LCP3 may be disposed on the first insulating layer 1515a. The plurality of third line connection patterns LCP3 may be electrically connected to the plurality of second line connection patterns LCP2. For example, the third line connection pattern LCP3 may be electrically connected to the second line connection pattern LCP2 through a contact hole of the first insulating layer 1515a.

A second insulating layer 1515b may be disposed on the plurality of third line connection patterns LCP3. The second insulating layer 1515b may be disposed in the display area DA, the first non-display area NDA1, and the second non-display area NDA2, and may not be disposed in all or a portion of the bending area BA, but implementations of the present disclosure are not limited thereto. For example, the second insulating layer 1515b may be removed from whole or a portion of the bending area BA. The second insulating layer 1515b may be formed of an organic insulating material, but implementations of the present disclosure are not limited thereto. For example, the second insulating layer 1515b may be formed of a photo resist, polyimide (PI), a photo acryl-based material, or the like, but implementations of the present disclosure are not limited thereto.

A plurality of fourth line connection patterns LCP4 may be disposed on the second insulating layer 1515b. The plurality of fourth line connection patterns LCP4 may be electrically connected to the plurality of third line connection patterns LCP3. For example, the fourth line connection pattern LCP4 may be electrically connected to the third line connection pattern LCP3 through a contact hole of the second insulating layer 1515b.

Referring to FIG. 8, according to implementations of the present disclosure, a plurality of pad connection patterns PCP may be disposed on the second protective layer 1513b in the non-display area NDA. The plurality of pad connection patterns PCP may be wires for transferring a signal transferred from the flexible printed circuit 102 to the pad part 211 to the driver DRV of the display area DA. For example, the plurality of pad connection patterns PCP may be electrically connected to the plurality of pads PD and may receive a signal from the flexible printed circuit 102 through the plurality of pads PD. The flexible printed circuit 102 may be connected to a printed circuit board 104 (see FIGS. 1 and 2).

For example, the plurality of pad connection patterns PCP may extend from the pad part 211 toward the display area DA and transmit a signal to a wiring of the display area DA. In this case, the plurality of pad connection patterns PCP may function as link lines LL (see FIG. 7). The plurality of pad connection patterns PCP may include a first pad connection pattern PCP1, a second pad connection pattern PCP2, a third pad connection pattern PCP3, and a fourth pad connection pattern PCP4.

The plurality of first pad connection patterns PCP1 may be disposed on the second protective layer 1513b. Each of the plurality of first pad connection patterns PCP1 may be disposed on the second non-display area NDA2, the bending area BA, and the first non-display area NDA1. Each of a plurality of first pad connection patterns PCP1 may include a first portion disposed in the bending area BA, a second portion extending from the first portion to the first non-display area NDA1, and a third portion extending from the first portion to the second non-display area NDA2. Each of the plurality of first pad connection patterns PCP1 may further extend from the first non-display area NDA1 to a partial area of the display area DA. The plurality of first pad connection patterns PCP1 may transfer signals transferred from the flexible printed circuit 102 to the pad part 211 to the driver DRV of the display area DA.

Each of the plurality of first pad connection patterns PCP1 may be electrically connected to the pad PD of the pad part 211 through connection patterns disposed in the second non-display area NDA2. Here, the connection patterns electrically connecting each of the plurality of first pad connection patterns PCP1 to the pad PD may include at least one of the second pad connection pattern PCP2, the third pad connection pattern PCP3, and the fourth pad connection pattern PCP4 disposed in the second non-display area NDA2.

Each of the plurality of first pad connection patterns PCP1 may be electrically connected to the driver DRV through connection patterns disposed in the display area DA. Here, the connection patterns electrically connecting each of the plurality of first pad connection patterns PCP1 to the driver DRV may include at least one of the second pad connection pattern PCP2, the third pad connection pattern PCP3, and the fourth pad connection pattern PCP4 disposed in the display area DA.

The plurality of second pad connection patterns PCP2 may be disposed on the third protective layer 1514. The plurality of second pad connection patterns PCP2 may be disposed in the second non-display area NDA2. The second pad connection pattern PCP2 may be electrically connected to the first pad connection pattern PCP1 through a contact hole of the third protective layer 1514. Therefore, a signal supplied from the flexible printed circuit 102 may be transferred to the first pad connection pattern PCP1 through the second pad connection pattern PCP2.

The third pad connection pattern PCP3 may be disposed on the first insulating layer 1515a. The third pad connection pattern PCP3 may be disposed in the second non-display area NDA2. The third pad connection pattern PCP3 may be electrically connected to the second pad connection pattern PCP2 through a contact hole of the first insulating layer 1515a. Therefore, a signal supplied from the flexible printed circuit 102 may be transmitted to the second pad connection pattern PCP2 through the third pad connection pattern PCP3, and a signal transmitted to the second pad connection pattern PCP2 may be transmitted to the first pad connection pattern PCP1 again.

The fourth pad connection pattern PCP4 may be disposed on the second insulation layer 1515b. The fourth pad connection pattern PCP4 may be disposed in the second non-display area NDA2. The fourth pad connection pattern PCP4 may be electrically connected to the third pad connection pattern PCP3 through a contact hole of the second insulation layer 1515b. The pad PD of the pad part 211 may be electrically connected to the fourth pad connection pattern PCP4 through a contact hole of the third insulation layer 1515c.

The signal supplied from the flexible printed circuit 102 may be input to the pad PD of the pad part 211, the signal input to the pad PD may be transmitted to the third pad connection pattern PCP3 through the fourth pad connection pattern PCP4, and the signal transmitted to the third pad connection pattern PCP3 may be transmitted to the first pad connection pattern PCP1 again through the second pad connection pattern PCP2. The signal transmitted to the first pad connection pattern PCP1 may be transmitted to the driver DRV through connection patterns disposed in the display area DA.

Referring to FIG. 8, the plurality of line connection patterns LCP and the plurality of pad connection patterns PCP may be disposed in various metal layers. The plurality of line connection patterns LCP and the plurality of pad connection patterns PCP may be formed of any one of a conductive material having excellent ductility or various conductive materials used in the display area DA.

For example, a metal pattern such as the first pad connection pattern PCP1 in which at least a portion is disposed in the bending area BA may be formed of a conductive material having excellent ductility, such as gold (Au), silver (Ag), or aluminum (Al), but implementations of the present disclosure are not limited thereto. For another example, the plurality of line connection patterns LCP and the plurality of pad connection patterns PCP may be formed of molybdenum (Mo), chromium (Cr), titanium (Ti), nickel (Ni), neodymium (Nd), copper (Cu), silver (Ag) and magnesium (Mg), or alloys thereof, but implementations of the present disclosure are not limited thereto.

A third insulating layer 1515c may be disposed on the plurality of line connection patterns LCP and the plurality of pad connection patterns PCP. The third insulating layer 1515c may be disposed in the display area DA, the first non-display area NDA1, and the second non-display area NDA2, and may be disposed in all or a portion of the bending area BA, but implementations of the present disclosure are not limited thereto. In the bending area BA, a portion of the third insulating layer 1515c may be removed. The third insulating layer 1515c may be formed of an organic insulating material, but implementations of the present disclosure are not limited thereto. For example, the third insulating layer 1515c may be formed of a photo resist, polyimide (PI), a photo acryl-based material, or the like, but implementations of the present disclosure are not limited thereto.

A plurality of banks BNK may be disposed on the third insulating layer 1515c in the display area DA. The plurality of banks BNK may overlap at least a portion of each of the plurality of sub-pixels SPa, SPb, and SPc. For example, the first sub-pixel SPa may include a first light emitting device EDa that emits first color light, the second sub-pixel SPb may include a second light emitting device EDc that emits second color light, and the third sub-pixel SPc may include a third light emitting device EDc that emits third color light.

As an example, one light emitting device ED may be disposed on each of the plurality of banks BNK. As another example, two or more light emitting devices ED may be disposed on each of the plurality of banks BNK. Two or more light emitting devices ED disposed on each of the plurality of banks BNK may be the same type of light emitting devices. For example, the same type of light emitting devices may be light emitting devices that emit light of the same color. For example, two or more light emitting devices ED disposed on each of the plurality of banks BNK may include a main light emitting device and a redundancy light emitting device.

In the display area DA, a plurality of row connection electrodes RCE may be disposed on the third insulating layer 1515c. The plurality of row connection electrodes RCE may transfer the low potential voltage VSS output from the driver DRV to the row line RL.

In the display area DA, a plurality of column lines CL may be disposed on the third insulating layer 1515c. The plurality of column lines CL may be disposed in areas between the plurality of banks BNK. For example, the plurality of column lines CL may be disposed adjacent to any one of the plurality of banks BNK.

Each of the plurality of column lines CL may include a wiring portion and a column connection electrode CCE protruding from the wiring portion. The wiring portion and the column connection electrode CCE included in each of the plurality of column lines CL may be integrally formed or may be different metals electrically connected to each other.

For example, each of the plurality of column lines CL may include a column connection electrode CCE that is protruding portion upward from an adjacent bank BNK of the plurality of banks BNK. The column connection electrodes CCE of each of the plurality of column lines CL may extend on side and upper surfaces of the bank BNK. The column connection electrode CCE may be an electrode electrically connected to each of the plurality of column lines CL or a portion protruding from each of the plurality of column lines CL.

According to implementations of the present disclosure, at least two of the column connection electrode CCE, the column line CL, the row connection electrode RCE, and the pad PD may be disposed on the same layer. The column connection electrode CCE, the column line CL, the row connection electrode RCE, and the pad PD may be formed of a single layer or multiple layers of conductive material, but implementations of the present disclosure are not limited thereto. For example, at least two of the column connection electrode CCE, the column line CL, the row connection electrode RCE, and the pad PD may be formed of multiple layers of indium tin oxide (ITO)/titanium (Ti)/aluminum (Al)/titanium (Ti), but implementations of the present disclosure are not limited thereto.

According to implementations of the present disclosure, a solder pattern SDP may be disposed on the column connection electrode CCE in each of the plurality of subpixels. The solder pattern SDP may bond the light emitting device ED to the column connection electrode CCE. The column connection electrode CCE and the light emitting device ED may be electrically connected to each other through eutectic bonding using the solder pattern SDP, but implementations of the present disclosure are not limited thereto. For example, when the solder pattern SDP is formed of indium (In), and the first electrode Ecl of the light emitting device ED is formed of gold (Au), the solder pattern SDP and the first electrode Ecl of the light emitting device ED may be bonded to each other by applying heat and pressure in a transfer process of the light emitting device ED. The light emitting device ED may be bonded to the solder pattern SDP and the column connection electrode CCE without a separate adhesive by eutectic bonding. For example, the solder pattern SDP may be formed of indium (In), tin (Sn), or alloys thereof, but implementations of the present disclosure are not limited thereto. For example, the solder pattern SDP may be a bonding pad or a connection pad, but implementations of the present disclosure are not limited thereto.

According to implementations of the present disclosure, a passivation layer 1516 may be disposed on the plurality of column lines CL, the plurality of column connection electrodes CCE, the plurality of row connection electrodes RCE, and the third insulation layer 1515c.

For example, the passivation layer 1516 may be disposed in the display area DA, the first non-display area NDA1, and the second non-display area NDA2. At least a portion of the passivation layer 1516 may be removed from the whole or a portion of the bending area BA. A portion of the passivation layer 1516 covering the plurality of pads PD may be removed in the second non-display area NDA2.

Since the passivation layer 1516 may cover the remaining area except for an area in which the bending area BA, the plurality of pads PD, and the solder pattern SDP are disposed, penetration of moisture or impurities flowing into the light emitting device ED may be reduced. For example, the passivation layer 1516 may be composed of a single layer or multiple layers of silicon oxide (SiOx) or silicon nitride (SiNx), but implementations of the present disclosure are not limited thereto. For example, the passivation layer 1516 may be a protective layer, an insulating layer, or the like, but implementations of the present disclosure are not limited thereto.

According to implementations of the present disclosure, the light emitting device ED has been described as a vertical structure, but implementations of the present disclosure are not limited thereto. For example, the light emitting device ED may have a lateral structure or a flip chip structure.

According to implementations of the present disclosure, a first optical layer 1517a surrounding the plurality of light emitting devices ED may be disposed in the display area DA. For example, the first optical layer 1517a may cover the plurality of light emitting devices ED and the bank BNK in the plurality of subpixels SP. For example, the first optical layer 1517a may cover the bank BNK, a portion of the passivation layer 1516, and areas between the plurality of light emitting devices ED. The first optical layer 1517a may be disposed or covered between the plurality of light emitting devices ED included in one pixel and between the plurality of banks BNK. For example, the first optical layer 1517a may extend in a first direction X and may be spaced apart from each other in a second direction Y. For example, the first optical layer 1517a may be disposed between the passivation layer 1516 and the row line RL to surround a side portion of the light emitting device ED and the bank BNK, but implementations of the present disclosure are not limited thereto. For example, the first optical layer 1517a may be a diffusion layer, a sidewall diffusion layer, or the like, but implementations of the present disclosure are not limited thereto.

The first optical layer 1517a may include an organic insulating material in which fine particles are distributed, but implementations of the present disclosure are not limited thereto. For example, the first optical layer 1517a may be formed of siloxane in which fine metal particles such as titanium dioxide (TiO2) particles are distributed, but implementations of the present disclosure are not limited thereto. Light from the plurality of light emitting devices ED may be scattered by fine particles distributed in the first optical layer 1517a and emitted to an outside of the display device 100. Accordingly, the first optical layer 1517a may improve extraction efficiency of light emitted from the plurality of light emitting devices ED.

For example, the first optical layer 1517a may be disposed in each of the plurality of pixels or may be disposed in some pixels disposed in the same row, but implementations of the present disclosure are not limited thereto. For example, the first optical layer 1517a may be disposed in each of the plurality of pixels, or the plurality of pixels may share one first optical layer 1517a. For another example, each of the plurality of sub-pixels may separately include the first optical layer 1517a, but implementations of the present disclosure are not limited thereto.

According to implementations of the present disclosure, in the display area DA, a second optical layer 1517b may be disposed on the passivation layer 1516. For example, the second optical layer 1517b may be disposed to surround the first optical layer 1517a. For example, the second optical layer 1517b may be in contact with a side surface of the first optical layer 1517a. For example, the second optical layer 1517b may be disposed in areas between the plurality of pixels. However, implementations of the present disclosure are not limited thereto, for example, the second optical layer 1517b may be a diffusion layer, a diffusion layer window, a window diffusion layer, or the like, but implementations of the present disclosure are not limited thereto.

The second optical layer 1517b may be formed of an organic insulating material, but implementations of the present disclosure are not limited thereto. The second optical layer 1517b may be formed of the same or substantially same material as the first optical layer 1517a, but implementations of the present disclosure are not limited thereto. For example, the first optical layer 1517a may include fine particles, and the second optical layer 1517b may not include fine particles. For example, the second optical layer 1517b may be formed of siloxane, but implementations of the present disclosure are not limited thereto.

For example, a thickness of the first optical layer 1517a may be less than a thickness of the second optical layer 1517b, but implementations of the present disclosure are not limited thereto. Accordingly, when viewed in a plan view, an area in which the first optical layer 1517a is disposed may include a concave portion recessed from an upper surface of the second optical layer 1517b.

According to implementations of the present disclosure, a row line RL may be disposed on the first optical layer 1517a and the second optical layer 1517b. For example, the row line RL may be electrically connected to the plurality of row connection electrodes RCE through a contact hole of the second optical layer 1517b. For example, the row line RL may be disposed on the plurality of light emitting devices ED. For example, the row line RL may include a transparent conductive oxide such as indium tin oxide (ITO) or indium zinc oxide (IZO), but implementations of the present disclosure are not limited thereto. For example, the row line RL may be in contact with the second electrode Erl of the light emitting device ED. For example, the row line RL may overlap the first optical layer 1517a. For example, the row line RL may cover an outer plane of the first optical layer 1517a.

The row lines RL may extend continuously in the first direction X of the substrate 210. Accordingly, the row lines RL may be connected in common to the plurality of pixels arranged in the first direction X of the substrate 210. For example, the row lines RL may be connected in common to the plurality of pixels.

According to implementations of the present disclosure, the row line RL may extend continuously on the first optical layer 1517a, the second optical layer 1517b, and the light emitting device ED. An area in which the first optical layer 1517a is disposed may include a concave portion recessed from the upper surface of the second optical layer 1517b. Accordingly, since a first portion of the row line RL disposed on the first optical layer 1517a is disposed along the concave portion, the first portion may be disposed at a lower position than a second portion of the row line RL disposed on the second optical layer 1517b.

A third optical layer 1517c may be disposed on the row line RL. The third optical layer 1517c may overlap the plurality of light emitting devices ED and the first optical layer 1517a. Since the third optical layer 1517c is disposed on the row line RL and the plurality of light emitting devices ED, mura that may occur in some of the plurality of light emitting devices ED may be improved. For example, when the plurality of light emitting devices ED are transferred on the substrate 210 of the display panel 110, an area in which a gap between the plurality of light emitting devices ED is not uniform due to a process deviation, etc. When the gap between the plurality of light emitting devices ED is non-uniform, a light emitting regions of each of the plurality of light emitting devices ED may be non-uniformly disposed, and thus mura may be visually recognized by a user. Accordingly, since the third optical layer 1517c uniformly diffuse light over an upper portion of a plurality of light emitting devices ED is configured, it is possible to reduce visibility of light emitted from some light emitting devices ED like mura. Therefore, since the light emitted from the plurality of light emitting devices ED is evenly diffused by the third optical layer 1517c and extracted to an outside of the display device 100, a luminance uniformity of the display device 100 may be improved.

The third optical layer 1517c may be formed of an organic insulating material in which fine particles are distributed, but implementations of the present disclosure are not limited thereto. For example, the third optical layer 1517c may be formed of siloxane in which fine metal particles such as titanium dioxide (TiO2) particles are distributed, but implementations of the present disclosure are not limited thereto. For example, the third optical layer 1517c may be formed of the same or substantially same material as the first optical layer 1517a, but implementations of the present disclosure are not limited thereto. For example, the third optical layer 1517c may be a diffusion layer, an upper diffusion layer, or the like, but implementations of the present disclosure are not limited thereto.

According to implementations of the present disclosure, light from the plurality of light emitting devices ED may be scattered by fine particles distributed in the third optical layer 1517c and emitted to the outside of the display device 100. The third optical layer 1517c may evenly mix light emitted from the plurality of light emitting devices ED to further improve luminance uniformity of the display device 100. In addition, light extraction efficiency of the display device 100 may be improved by light scattered from the plurality of fine particles, and thus the display device 100 may be driven at a low power.

In the display area DA, a black matrix BM may be disposed on the row line RL, the first optical layer 1517a, the second optical layer 1517b, and the third optical layer 1517c. For example, the black matrix BM may fill a contact hole of the second optical layer 1517b. Since the black matrix BM may cover the display area DA, color mixing and reflection of external light of the plurality of subpixels may be reduced. For example, since the black matrix BM is disposed in a contact hole in which the row line RL and the row connection electrode RCE are connected, light leakage between the plurality of neighboring subpixels may be reduced or prevented.

For example, the black matrix BM may be formed of an opaque material, but implementations of the present disclosure are not limited thereto. For example, the black matrix BM may be an organic insulating material to which a black pigment or a black dye is added, but implementations of the present disclosure are not limited thereto.

In the display area DA, a cover layer 1518 may be disposed on the black matrix BM. The cover layer 1518 may protect an element under the cover layer 1518. For example, the cover layer 1518 may be formed of an organic insulating material, but implementations of the present disclosure are not limited thereto. For example, the cover layer 1518 may be formed of a photo resist, polyimide (PI), a photo acryl-based material, or the like, but implementations of the present specification are not limited thereto. For example, the cover layer 1518 may be an overcoating layer, an insulating layer, or the like, but implementations of the present disclosure are not limited thereto.

A polarizing layer 114 may be disposed on the cover layer 1518 via a first adhesive layer 112. A cover member 118 may be disposed on the polarizing layer 114 via a second adhesive layer 116. For example, the first adhesive layer 112 and the second adhesive layer 116 may include an optically clear adhesive (OCA), an optically clear resin (OCR), a pressure sensitive adhesive (PSA) or the like, but implementations of the present disclosure are not limited thereto.

According to implementations of the present disclosure, the plurality of pads PD may be disposed on the third insulating layer 1515c in the second non-display area NDA2. For example, at least portions of the plurality of pads PD may be exposed from the passivation layer 1516. For example, the plurality of pads PD may be electrically connected to the fourth pad connection pattern PCP4 through a contact hole of the third insulating layer 1515c.

An adhesive layer ACF may be disposed on the plurality of pads PD. The adhesive layer ACF may be an adhesive layer in which conductive balls are distributed in an insulating material, but implementations of the present disclosure are not limited thereto. When heat or pressure is applied to the adhesive layer ACF, the conductive balls may be electrically connected each other in a portion where heat or pressure is applied to have conductive characteristics. The adhesive layer ACF may be disposed between the plurality of pads PD and the flexible printed circuit 102 to attach or bond the flexible printed circuit 102 to the plurality of pads PD. For example, the adhesive layer ACF may be anisotropic conductive film (ACF), but implementations of the present disclosure are not limited thereto.

The flexible printed circuit 102 may be disposed on the adhesive layer ACF. The flexible printed circuit 102 may be electrically connected to the plurality of pads PD through the adhesive layer ACF. Therefore, a signal supplied from the flexible printed circuit 102 may be transferred to the driver DRV of the display area DA through the plurality of pads PD, the fourth pad connection pattern PCP4, the third pad connection pattern PCP3, the second pad connection pattern PCP2, and the first pad connection pattern PCP1.

Referring to FIG. 8, the display panel 110 according to implementations of the present disclosure may include a substrate 210, a layer stack 1410 on the plurality of drivers DRV disposed on the substrate 210, an optical layer 1517a disposed between the plurality of light emitting devices EDa, EDb, EDc, the adhesive layer 116 disposed on the optical layer 1517a and the plurality of light emitting devices EDa, EDb, EDc, and the cover member 118 disposed on the adhesive layer 116.

Referring to FIG. 8, the plurality of column lines CL may be disposed between the layer stack 1410 and the plurality of light emitting devices EDa, EDb, and EDc.

Referring to FIG. 8, the plurality of row lines RL may be disposed on the plurality of light emitting devices EDa, EDb, and EDc and the optical layer 1517a. plurality of row lines RL may be disposed between the plurality of light emitting devices EDa, EDb, and EDc, the optical layer 1517a and the adhesive layer 116.

Referring to FIG. 8, the layer stack 1410 may include the plurality of protective layers 1513a, 1513b, and 1514 disposed on the side and upper surfaces of each of the plurality of drivers DRV, the plurality of insulating layers 1515a, 1515b, and 1515c disposed on the plurality of protective layers, and the bank BNK disposed on the plurality of insulating layers.

The plurality of protective layers 1513a, 1513b, and 1514 may further include a side protective layer 1513 disposed on the side surface of each of the plurality of drivers DRV and an upper protective layer 1514 disposed on the upper surface of each of the plurality of drivers DRV.

The side protective layer 1513 may include a first protective layer 1513a disposed on the substrate 210 and a second protective layer 1513b disposed on the first protective layer 1513a.

The upper protective layer 1514 may include a second protective layer 1513b and a third protective layer 1514 disposed on the plurality of drivers DRVs.

The plurality of insulating layers 1515a, 1515b, and 1515c may include a first insulating layer 1515a disposed on the upper protective layer 1514, and a second insulating layer 1515b disposed on the first insulating layer 1515a. The plurality of insulating layers 1515a, 1515b, and 1515c may further include a third insulating layer 1515c disposed on the second insulating layer 1515b.

Each of the plurality of light emitting devices EDa, EDb, and EDc may be disposed on the bank BNK and positioned in an opening of the optical layer 1517a.

At least a portion of each of the plurality of column lines CL may extend on the bank BNK on the plurality of insulating layers 1515a, 1515b, and 1515c. Each of the plurality of row lines RL may be disposed on the optical layer 1517a and the plurality of light emitting devices EDa, EDb, and EDc.

The first electrode Ecl of each of the plurality of light emitting devices EDa, EDb, and EDc may be electrically connected to at least a portion of the column line CL extending on the bank BNK among the plurality of column lines CL. The second electrode Erl of each of the plurality of light emitting devices EDa, EDb, and EDc may be electrically connected to one of the plurality of row lines RL.

Referring to FIG. 8, the display panel 110 according to implementations of the present disclosure may include a plurality of line connection patterns LCP for connecting each of the plurality of lines including the plurality of row lines RL and the plurality of column lines CL to the plurality of drivers DRV.

The plurality of line connection patterns LCPs may include a first line connection pattern LCP1 disposed on the side protective layer 1513, a second line connection pattern LCP2 disposed on the upper protective layer 1514 and electrically connected to the first line connection pattern LCP1 through a hole of the upper protective layer 1514, a third line connection pattern LCP3 disposed on the first insulating layer 1515a and electrically connected to the second line connection pattern LCP2 through a hole of the first insulating layer 1515a, and a fourth line connection pattern LCP4 disposed on the second insulating layer 1515b and electrically connected to the third line connection pattern LCP3 through a hole of the second insulating layer 1515b.

The first line connection pattern LCP1 may be electrically connected to one of the plurality of drivers DRVs. The fourth line connection pattern LCP4 may be electrically connected to at least one second electrode Erl of the plurality of light emitting devices EDa, EDb, and EDc, or may be electrically connected to at least one first electrode Ecl of the plurality of light emitting devices EDa, EDb, and EDc.

The side protective layer 1513 disposed on the side surfaces of each of the plurality of drivers DRV may include two or more organic layers.

Each of the first and second protective layers 1513a and 1513b which are the side protective layers 1513, the third protective layer 1514 which is the upper protective layer 1514 and the first to third insulating layers 1515a, 1515b and 1515c may be formed of an organic layer.

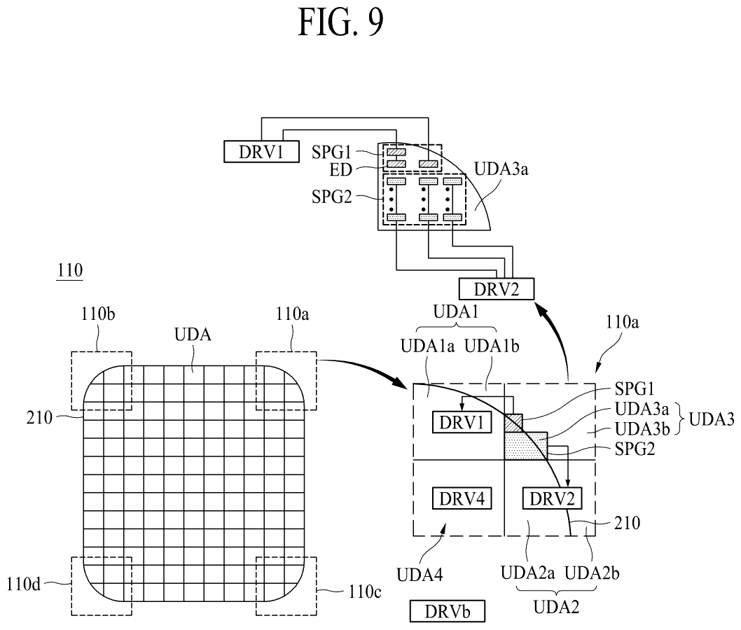

FIG. 9 is a view illustrating the substrate 210 including a plurality of peripheral portions in a display device according to implementations of the present disclosure.

Referring to FIG. 9, the display panel 110 may include a plurality of unit driving areas UDA. Referring to FIG. 9, the unit driving area UDA is shown as a square. The substrate 210 may include unit driving areas UDA having a rectangular shape. The substrate 210 may have a rectangular shape, and in this case, corners of the rectangular shape may have a rounded shape.

Referring to FIG. 9, the substrate 210 may include a plurality of peripheral portions 110a, 110b, 110c, and 110d. Each of the plurality of peripheral portions 110a, 110b, 110c, and 110d may have a round shape or a curved shape.

Referring to FIG. 9, a first peripheral portion 110a may be positioned at a right upper end of the substrate 210, and a second peripheral portion 110b may be positioned at a left upper end of the substrate 210. A third peripheral portion 110c may be positioned at a right lower end of the substrate 210, and a fourth peripheral portion 110d may be positioned at a left lower end of the substrate 210.

Referring to FIG. 9, it may be seen that the first peripheral portion 110a is enlarged.

Referring to FIG. 9, the first peripheral portion 110a may include four unit driving areas UDA1, UDA2, UDA3, and UDA4.

A first unit driving area UDA1 may be an area of a left upper end of the first peripheral portion 110a. The first unit driving area UDA1 may be an area in which a first driver DRV1 is disposed. The first unit driving area UDA1 may include a first sub-pixel arrangement area UDA1a and a first peripheral area UDA1b. The first sub-pixel arrangement area UDA1a may be an area in which the plurality of sub-pixels SP are disposed. The first peripheral area UDA1b may be an area corresponding to an outer periphery of the first sub-pixel arrangement area UDA1a. A boundary between the first sub-pixel arrangement area UDA1a and the first peripheral area UDA1b may have a curved shape. The first peripheral area UDA1b may be an area where the light emitting device ED is not disposed. For example, the first peripheral area UDA1b may the non-display area NDA, the first non-display area NDA1, the bending area BA, or a shielding area of the black matrix BM, but is not limited thereto. Alternatively, the first peripheral area UDA1b may be an area where a portion of the substrate 210 is cut and removed, but is not limited thereto.

A second unit driving area UDA2 may be an area under a right lower end of the first peripheral portion 110a. The second unit driving area UDA2 may be an area where a second driver DRV2 is disposed. The second unit driving area UDA2 may include a second sub-pixel arrangement area UDA2a and a second peripheral area UDA2b.

A third unit driving area UDA3 may be an area of an upper right end of the first peripheral portion 110a. The third unit driving area UDA3 may be an area where the driver DRV is not disposed. The third unit driving area UDA3 may include a third sub-pixel arrangement area UDA3a and a third peripheral area UDA3b. A boundary between the third sub-pixel arrangement area UDA3a and the third peripheral area UDA3b may extend to the boundary between the first sub-pixel arrangement area UDA1a and the first peripheral area UDA1b. The boundary between the third sub-pixel arrangement area UDA3a and the third peripheral area UDA3b may extend to the boundary between the second sub-pixel arrangement area UDA2a and the second peripheral area UDA2b.

A fourth unit driving area UDA4 may be an area of a left lower end of the first peripheral portion 110a. The fourth unit driving area UDA4 may be an area in which a fourth driver DRV4 is disposed. Therefore, three drivers DRV1, DRV2, and DRV4 may be disposed in the first peripheral portion 110a.

In the third unit driving area UDA3, the third sub-pixel arrangement area UDA3a is narrower than the other sub-pixel arrangement areas UDA1a and UDA2a, and an arrangement of the light emitting device ED may be less.

In other words, the third peripheral area UDA3b may be relatively wider than the other peripheral areas UDA1b and UDA2b. Accordingly, the position at which the driver DRV is to be disposed may be relatively insufficient in the third unit driving area UDA3. Accordingly, the driver DRV may not be disposed in the third unit driving area UDA3.

Referring to FIG. 9, the plurality of subpixels SP disposed in the third unit driving area UDA3 may be showed.

Since the driver DRV is not disposed in the third unit driving area UDA3, the drivers DRV1 and DRV2 located in areas other than the third unit driving area UDA3 may drive the plurality of subpixels SP disposed in the third unit driving area UDA3.

Referring to FIG. 9, the first driver DRV1 may drive a first sub-pixel group SPG1 disposed in the third unit driving area UDA3. The second driver DRV2 may drive a second sub-pixel group SPG2 disposed in the third unit driving area UDA3.

For example, it is illustrated that the first sub-pixel group SPG1 includes three sub-pixels SP, and the second sub-pixel group SPG2 includes at least six sub-pixels SP. However, the number of sub-pixels SP included in the sub-pixel groups SPG1 and SPG2 is not limited thereto.

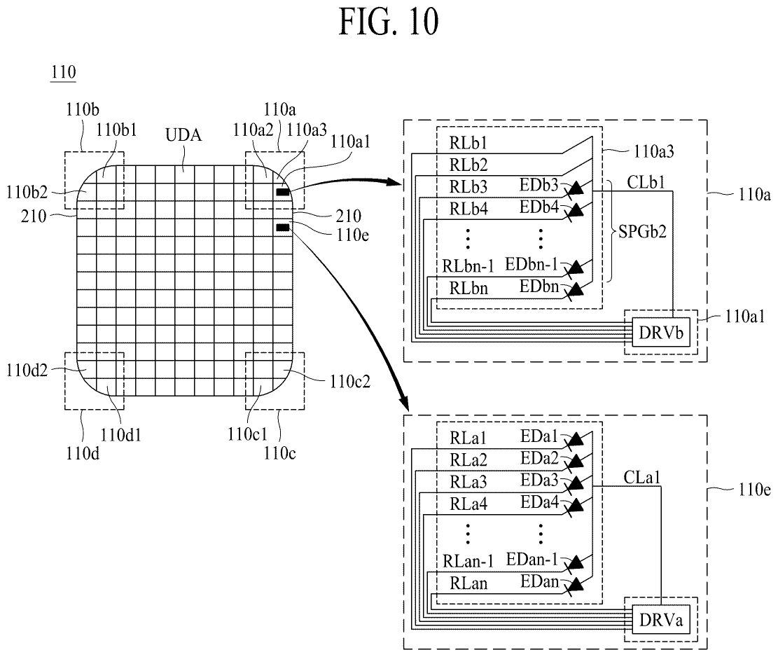

FIG. 10 is a diagram illustrating a connection relationship between a driver DRV and subpixels SP disposed in a unit driving area UDA in a display device according to implementations of the present disclosure.

A connection relationship between a driver DRVa disposed in a central area 110e, a driver DRVb disposed in the peripheral portion and a subpixel disposed in the unit driving area UDA will be described. For convenience of description, it will be assumed that the driver DRVa disposed in the central area 110e drives n light emitting devices. In the peripheral portion, an area where the driver DRV is not disposed may be a non-driver area 110a3.

Referring to FIG. 9 and FIG. 10 together, the driver DRVa of the central area 110e may be disposed in the central area 110e to be electrically connected to n light emitting devices EDs of subpixels disposed in the central area 110e.

In the central area 110e, a first light emitting device EDa1 may be electrically connected between a first row line RLa1 and a first column line CLa1. A second light emitting device EDa2 may be electrically connected between a second row line RLa2 and the first column line CLa1. Since the above-described characteristics are the same or substantially same in the third light emitting device EDa3 to nth light emitting device EDan, repeated descriptions thereof will be omitted.

Subsequently, the first peripheral portion 110a may include a first peripheral portion 110a1 and a second peripheral portion 110a2. A peripheral portion driver DRVb may be disposed in the first peripheral portion 110a1, and the peripheral portion driver DRVb may drive sub-pixels disposed in a unit driving area UDA other than the unit driving area UDA in which the peripheral portion driver DRVb is disposed.

For example, the peripheral portion driver DRVb may disposed in the first peripheral portion 110a1. The peripheral portion driver DRVb disposed in the first peripheral portion 110a1 may be electrically connected to the sub-pixels of the first peripheral part 110a1, and may also be electrically connected to the first sub-pixel group SPG1 disposed in the non-driver area 110a3. This is the same or substantially same for the driver DRVb disposed in the second peripheral portion 110a2. The driver DRVb disposed in the second peripheral portion 110a2 may be electrically connected to the second sub-pixel group SPG2.

As described above, the number of sub-pixels driven by the peripheral portion driver DRVb may be different from the number of sub-pixels driven by the driver DRVa of the central area 110e. In other words, a portion of the substrate is removed in the plurality of peripheral portions 110a, 110b, 110c, and 110d to have a round shape or a curved shape, and thus an area of the non-driver area 110a3 may be narrower than an area of the central area 110e. Accordingly, the number of sub-pixels driven by the peripheral portion driver DRVb may be relatively less than the number of sub-pixels driven by the driver DRVa of the central area 110e.

For example, while the driver DRVa of the central area 110e drives the first light emitting device EDa1 and the second light emitting device EDa2, the peripheral portion driver DRVb may drive only the third light emitting device EDa3 to nth light emitting device EDan without driving the light emitting device ED and the light emitting device ED corresponding to the first light emitting device EDa1 and the second light emitting device EDa2.

In the first peripheral portion 110a1, the light emitting device ED may not be connected between the first row line RLb1 and the first column line CLb1. Likewise, the light emitting device ED may not be connected between the second row line RLb2 and the first column line CLa1. A third light emitting device EDb3 may be electrically connected between the third row line RLb3 and the first column line CLa1. Hereinafter, the remaining fourth to nth light emitting devices EDb4 to EDbn may be electrically connected between the respective row lines and the first column line CLa1 in the same manner as in the central area 110e. Although the case where only the first light emitting device EDa1 and the second light emitting device EDa2 are not connected has been described, the present disclosure is not limited thereto.

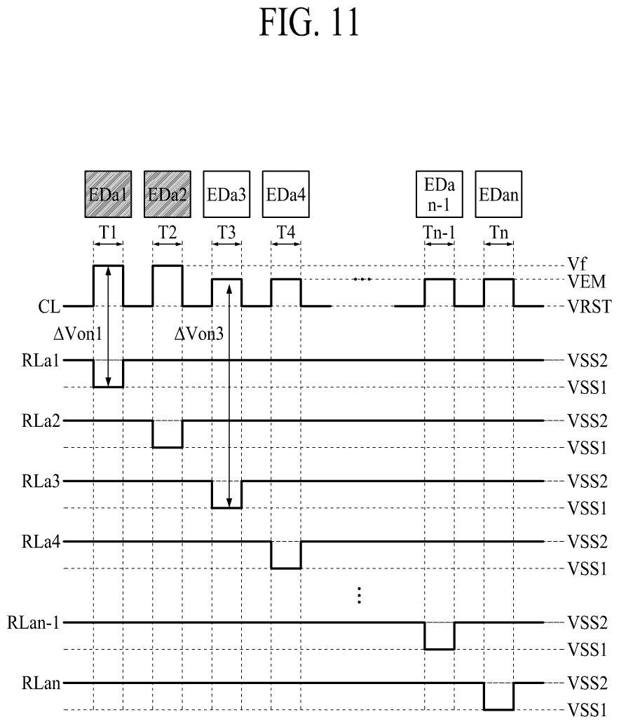

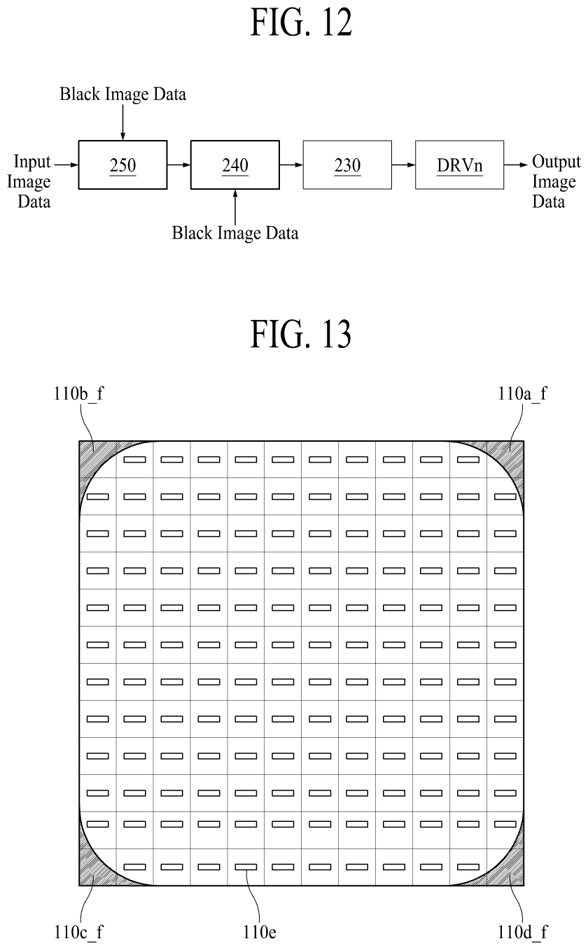

FIG. 11 is a diagram for describing a driving timing of a driver DRV disposed at a peripheral portion 110a, 110b, 110c and 110d of a display device according to implementations of the present disclosure. FIG. 12 is a diagram illustrating an operation of a controller circuit in a display device according to implementations of the present disclosure. FIG. 13 is a diagram illustrating data input for each area in a display device according to implementations of the present disclosure.

Referring to FIGS. 9 to 13, it will be described together.

Referring to FIGS. 9 to 13, first, during the (n−1)th driving period Tn−1 in the central area 110e, a state of a voltage of the (n−1)th row line RLan-1 may change from the second low potential voltage VSS2 to the first low potential voltage VSS1. In this case, a state of a voltage of the first column line CLa1 may change from a reset voltage VRST to a display voltage VEM. A voltage difference between the (n−1)th row line RLan-1 and the first column line CLa1 may become a display-on voltage Von, wherein the (n−1)th light emitting device EDan-1 may emit light. Thereafter, the state of the voltage of the (n−1)th row line RLan-1 is changed again from the first low potential voltage VSS1 to the second low potential voltage VSS2.

Next, during the nth driving period Tn, the same or substantially same characteristics as in the n−1th row line RLan-1 are repeated in the nth row line RLan, and the state of the voltage of the first column line CLa1 is also repeated.

The light emitting device ED may emit light when a difference in voltage between both ends of the light emitting device ED is equal to or greater than the display-on voltage Von. Although the light emitting device ED may be turned on only by control to make the difference in voltage between both ends of the light emitting device ED the display-on voltage Von, the light emitting device may be turned on at an undesired time for various reasons.

Referring to FIGS. 9 to 11, the driver DRVa of the central area 110e described above may supply the display voltage VEM to the first column line CLa1 during the first driving period T1. Since the first light emitting device EDa1 emits light during the first driving period T1, current flows through the first light emitting device EDa1.

On the other hand, even if the peripheral portion driver DRVb supplies the display voltage VEM to the first column line CLb1 during the first driving period T1, the first light emitting device EDb1 does not exist and thus the current cannot flow through the first light emitting device EDb1. Accordingly, current does not escape through the first light emitting device EDb1, and accordingly, a voltage level of the first column line CLb1 is increased to a floating voltage Vf. When the voltage level of the first column line CLb1 increases to the floating voltage Vf, the voltage difference ΔVon1 between the first column line CLb1 and the first row line RLb1 increases, and thus the third light emitting device EDb3 to the nth light emitting device EDbn may unintentionally emit light.

To prevent this, the peripheral portion driver DRVb may drive the first column line CLb1 by dividing it into a black driving period and a normal driving period.

For example, the black driving period may be the first and second driving periods T1 and T2, and the normal driving period may be the third to nth driving periods T3 to Tn.

Referring to FIG. 12, a control unit 250 corresponding to an external system 250 or a second circuit component 240 such as a timing controller may supply a black image data to the plurality of peripheral portion drivers DRVb, so that output image data including the black image data may be applied to the first column line CLb1 during the black driving period corresponding to the first and second driving periods T1 and T2. In other words, while the first row line RLb1 or the second row line RLb2 is supplied with the first low-potential voltage VSS1, output image data corresponding to the black image data may be applied to the first column line CLb1.

Referring to FIG. 11, during the normal driving period corresponding to the third to nth driving periods T3 to Tn, the controller circuit supplies normal data to the peripheral portion driver DRVb, and thus the voltage difference ΔVon3 between the third column line CLb3 and the first row line RLb1 may be the normal display-on voltage Von. Since this is the same for the other row lines, repeated descriptions thereof will be omitted.

In general, the black driving period may be shorter than the normal driving period, but is not limited thereto and may be determined according to the number of light emitting devices ED between the row line and the column line.

As described above, the plurality of peripheral portions may be driven in the black driving period and the normal driving period. When the display device 100 has four peripheral portions as shown in FIG. 13, the peripheral areas 110a_f, 110b_f, 110c_f, and 110d_f may refer to column lines and row lines to which the light emitting device ED is not connected in the plurality of peripheral portion portions. Accordingly, the black image data applied during the black driving period may be output image data with respect to the peripheral areas 110a_f, 110b_f, 110c_f, and 110d_f.

In this way, when the display device 100 has the plurality of peripheral portions, the controller circuits, such as 240 and 250 may modulate the input image data in a rectangular shape input from the outside into the black image data, and the plurality of peripheral portion driver DRVb may drive the output image data by dividing the driving period into the black driving period and the normal driving period.

In addition, even if there is no light emitting device ED between the first row line RLb1 or the second row line RLb2 and the first column line CLb1, the black image data is supplied to the first column line CLb1. Therefore, the voltage level of the first column line CLb1 does not rise to the floating voltage Vf, and the third to nth light emitting devices EDb3 to EDbn may not emit light. In addition, even if the third to nth light emitting devices EDb3 to EDbn emit light during the black driving period, it may not be recognized as a defective phenomenon because it is in a black gray level state. Alternatively, even if the third to nth light emitting devices EDb3 to EDbn emit light during the black driving period, it may be in a relatively low gray level state compared to the light emitting device ED of the adjacent sub-pixel.

The implementations of the present disclosure described above will be briefly described as follows.

The display according to the implementations of the present disclosure includes a substrate divided into a unit driving area including a plurality of light emitting devices and including a plurality of peripheral portions and a central area different from the plurality of peripheral portions, a first driver disposed in the plurality of peripheral portions and driving the plurality of light emitting devices in the plurality of peripheral portions, a second driver disposed in the central area and driving the plurality of light emitting devices in the central area, and a controller circuit driving the first driver and the second driver, and wherein the number of light emitting devices driven by the first driver is different from the number of light emitting devices driven by the second driver.

In the display according to the implementations of the present disclosure, each of the plurality of peripheral portions includes a sub-pixel arrangement area in which the plurality of light emitting devices are disposed and a peripheral area outside the sub-pixel arrangement area

In the display according to the implementations of the present disclosure, the sub-pixel arrangement area is divided into a peripheral portion driver area in which the first driver is disposed and a non-driver area in which the first driver is not disposed.

In the display according to the implementations of the present disclosure, the plurality of light emitting devices in the peripheral portion driver area and the non-driver area are driven by the first driver.

In the display according to the implementations of the present disclosure, a data including a black image data that is not supplied to the plurality of light emitting devices is applied to the first driver.

In the display according to the implementations of the present disclosure, the first driver includes a plurality of column lines and a plurality of row lines connected to the plurality of light emitting devices, and the light emitting device is not disposed between the at least one column line and the at least one row line.

In the display according to the implementations of the present disclosure, the number of light emitting devices connected to at least one column line is different from the number of light emitting devices connected to another column line.

In the display according to the implementations of the present disclosure, in the first driver, the number of light emitting devices connected to at least one column line is less than the number of light emitting devices connected to another column line.

In the display according to the implementations of the present disclosure, the data including the black image data is applied to the at least one column line having a different number of connected light emitting devices.

In the display according to the implementations of the present disclosure, the black image data is not applied to the plurality of light emitting devices.

In the display according to the implementations of the present disclosure, the at least one column line having a different number of connected light emitting devices is driven by dividing into a black driving period and a normal driving period.

In the display according to the implementations of the present disclosure, the black image data is applied in the black driving period.

In the display according to the implementations of the present disclosure, during the black driving period, the plurality of light emitting devices connected to the at least one column line do not emit light.

In the display according to the implementations of the present disclosure, the black driving period is shorter than the normal driving period.

In the display according to the implementations of the present disclosure, the controller circuit receives an input data and modulates the input data to include the black image data.

In the display according to the implementations of the present disclosure, the controller circuit supplies a data including the black image data to the first driver.

In the display according to the implementations of the present disclosure, the controller circuit stores position information for applying the black image data.

In the display according to the implementations of the present disclosure, the controller circuit is disposed outside the substrate.

In the display according to the implementations of the present disclosure, the peripheral portion includes a first unit driving area and a second unit driving area, the first unit driving area includes a first sub-pixel arrangement area and a first peripheral area, the second unit driving area includes a second sub-pixel arrangement region and a second peripheral area, and an area of the second sub-pixel arrangement area is narrower than an area of the first sub-pixel arrangement area.

In the display according to the implementations of the present disclosure, a boundary between the second sub-pixel arrangement area and the second peripheral area has a curved shape.

It will be apparent to those skilled in the art that the present disclosure described above is not limited by the above-described implementations and the accompanying drawings and that various substitutions, modifications and variations can be made in the present disclosure without departing from the technical ideas or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device comprising:
a substrate including a display area, the display area comprising a plurality of corner portions and a central area different from the plurality of corner portions;
a plurality of light emitting devices disposed within the display area;
a first driving circuit disposed in the plurality of corner portions and configured to drive the plurality of light emitting devices in the plurality of corner portions;
a second driving circuit disposed in the central area and configured to drive the plurality of light emitting devices in the central area; and
a controller circuit configured to drive the first driving circuit and the second driving circuit,
wherein the number of light emitting devices driven by the first driving circuit is different from the number of light emitting devices driven by the second driving circuit.

2. The display device of claim 1, wherein each of the plurality of corner portions includes a sub-pixel arrangement area in which a subset of the plurality of light emitting devices are disposed and a substrate removal area outside the sub-pixel arrangement area.

3. The display device of claim 2, wherein the sub-pixel arrangement area is divided into a corner portion driver area in which the first driving circuit is disposed and a non-driver area in which the first driving circuit is not disposed.

4. The display device of claim 3, wherein the plurality of light emitting devices in the corner portion driver area and the non-driver area are driven by the first driving circuit.

5. The display device of claim 3, wherein the controller circuit is configured to provide data including a black image data to the first driving circuit, wherein the black image data is for preventing light emission from at least one of the plurality of light emitting devices.

6. The display device of claim 1, wherein:
the first driving circuit is coupled to a plurality of column lines and a plurality of row lines connected to the plurality of light emitting devices; and
a light emitting device is not disposed at an intersection of at least one column line and at least one row line.

7. The display device of claim 6, wherein for the first driving circuit, the number of light emitting devices connected to the at least one column line is different from the number of light emitting devices connected to another column line.

8. The display device of claim 6, wherein for the first driving circuit, the number of light emitting devices connected to at least one column line is less than the number of light emitting devices connected to another column line.

9. The display device of claim 7, wherein the controller circuit is configured to provide data including a black image data for application to the at least one column line having a different number of connected light emitting devices.

10. The display device of claim 9, wherein application of the black image data to the at least one column line prevents light emission from any light emitting device connected to the at least one column line.

11. A display device comprising:
a substrate including a display area, the display area comprising a central area and a plurality of peripheral portions, wherein the display area includes a plurality of row lines and a plurality of column lines;
a plurality of light emitting devices each disposed at an intersection of one of the plurality of row lines and one of the plurality of the column lines;
a plurality of first driving circuits disposed within the plurality of peripheral portions and connected to a first subset of the plurality of row lines and the plurality of column lines located within the plurality of portions;
a plurality of second driving circuits disposed within the central area and connected to a second subset of the plurality of row lines and the plurality of column lines located within the central area; and
a controller circuit connected to the plurality of first driving circuits and the plurality of second driving circuits,
wherein, at least one of the peripheral portions comprises a sub-pixel arrangement area and a peripheral area, and
wherein within the peripheral area, a light-emitting device is not disposed at an intersection of a first column line and a first row line.

12. The display device of claim 11, wherein each of the plurality of peripheral portions includes a sub-pixel arrangement area in which the plurality of light emitting devices are disposed and a peripheral area outside the sub-pixel arrangement area.

13. The display device of claim 12, wherein the sub-pixel arrangement area is divided into a first area comprising one of the plurality of first driving circuits, and a non-driver area in which no driving circuit is disposed.

14. The display device of claim 13, wherein the one of the plurality of first driving circuits disposed in the first area is connected to the light emitting devices located in the non-driver area.

15. The display device of claim 11, wherein a number of light-emitting devices connected to the first column line is less than a number of light-emitting devices connected to a second column line located within the central area.

16. The display device of claim 15, wherein:
the first column line and a third column line are connected to the same one of the plurality of first driving circuits; and
the number of light emitting devices connected to the first column line is different from a number of light emitting devices connected to the third column line.

17. The display device of claim 16, wherein the number of light emitting devices connected to the first column line is less than the number of light emitting devices connected to the third column line.

18. A method of driving a display device, the display device comprising a substrate with a display area, the display area including a plurality of row lines, a plurality of column lines, a plurality of light-emitting devices disposed at intersections of the row lines and the column lines, and a controller circuit, the method comprising:
identifying, by the controller circuit, a target intersection of a target column line and a target row line within a peripheral portion of the display area at which no light emitting device is disposed; and
applying, by a driving circuit under control of the controller circuit, a data signal to the target column line during a driving period corresponding to the target row line, wherein applying the data signal prevents a voltage of the target column line from increasing to a floating voltage that would otherwise be caused by the absence of a light emitting device being disposed at the target intersection.

19. The method of claim 18, wherein the data signal comprises black image data.

20. The method of claim 19, further comprising:
receiving, by the controller circuit, input image data for a display; and
generating, by the controller circuit, the black image data by modulating the input image data based on the identified target intersection.
